(19) United States
(12) Patent Application Publication
(10) Pub. No.: US 2002/0027823 A1
(43) Pub. Date: Mar. 7, 2002

(54) Semiconductor memory device

(75) Inventors: Naoya Watanabe, Hyogo (JP); Aiko Nishino, Hyogo (JP); Katsumi Dosaka, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 09/839,401

(22) Filed: Apr. 23, 2001

(30) Foreign Application Priority Data
Sep. 6, 2000 (JP) 2000-270060(P)

(51) Int. Cl. G11C 8/00

(52) U.S. Cl. 365/230.03

(57) ABSTRACT

A main control circuit generates a plurality of main control signals of different phases to local control circuits. The local control circuits produce row-related control signals larger in number than the main control signals in accordance with these main control signals. A semiconductor memory device can be easily adapted to change in bank structure, and can perform a fast and stable operation with a low current consumption.

### BACKGROUND OF THE INVENTION

1. Field of the Invention

The present invention relates to a semiconductor memory device, and particularly to a semiconductor memory device having a large storage capacity. In particular, the present invention relates to row-related control circuitry for controlling a row selecting operation of a clock synchronous DRAM (Dynamic Random Access Memory) used, e.g., in a DRAM mounted on a common chip together with a logic or the like.

2. Description of the Background Art

FIG. 34 schematically shows a whole structure of a conventional clock synchronous semiconductor memory device. In FIG. 34, the clock synchronous semiconductor memory device includes a plurality of submemory arrays SMAO-SMA3, row decoders RDO-RD3 provided corresponding to sub-memory arrays SMAO-SMA3 for selecting rows of corresponding sub-memory arrays, respectively, a column decoder CDA provided for sub-memory arrays SMA0 and SMA2 for producing a column select signal for selecting columns in these sub-memory arrays, a column decoder CDB provided corresponding to sub-memory arrays SMA1 and SMA3 for producing the column select signal for selecting columns in these sub-memory arrays, a data path DPA for transmitting data to and from memory cells in the column selected by column decoder CDA, and a data path DPB for transmitting data to and from memory cells in the column selected by column decoder CDB. Each of data paths DPA and DPB includes data input circuits (an input buffer and a write buffer) and a data output circuit (an output buffer and a preamplifier).

Sub-memory arrays SMA0 and SMA1 form a bank BA#0, and submemory arrays SMA2 and SMA3 form a bank BA#0. Commonly to banks BA#1 and BA#0, there is arranged a main control circuit MCK that operates in synchronization with a clock signal CLK to receive an address signal ADD and a command CMD instructing an operation mode, and produces an operation control signal for banks BA#0 and BA#1. For bank BA#0, a sub-control circuit SCK0 is provided. For bank BA#1, a sub-control circuit SCK1 is provided. Main control circuit MCK produces an operation control signal for a designated bank in accordance with a bank address included in address signal ADD. Sub-control circuits SCK0 and SCK1 produce control signals for performing designated operations in accordance with the main operation control signal received from main control circuit MCK. These sub-control circuits SCK0 and SCK1 operate independently of each other in accordance with the operation control signal received from main control circuit MCK.

As shown in FIG. 34, the memory array is divided into two banks BA#0 and BA#1 so as to be activated and deactivated independently of each other in accordance with sub-control circuits SCK0 and SCK1, respectively. Therefore, the data access can be made to the banks in an interleaved manner, so that a penalty upon page switching is not caused, and fast access can be performed.

FIG. 35 schematically shows a structure of sub-memory arrays SMA0-SMA3 shown in FIG. 34. Sub-memory arrays SMA0-SMA3 have the same structure, and therefore FIG. 35 shows only one sub-memory array as a representative.

In FIG. 35, sub-memory array SMA includes a plurality of memory blocks MB0-MB7, a sense amplifier bands SAB1-SAB7 arranged between memory blocks MB0-MB7, and sense amplifier bands SAB0 and SAB8 arranged outside memory blocks MB0 and MB7, respectively.

In memory block MB0, memory cells are arranged in rows and columns. In sense amplifier bands SAB0-SAB8, sense amplifier circuits are arranged corresponding to the columns of corresponding memory blocks MB0-MB7. Sense amplifier bands SAB0-SAB8 have a so-called “alternately arranged, shared sense amplifier structure”, in which the sense amplifier circuits are arranged alternately on the opposite sides of the columns of the corresponding memory blocks, and each sense amplifier circuit is shared between the adjacent memory blocks.

In the sub-memory array SMA, the row selecting operation is performed on a block basis. One of the memory blocks is designated by the block select signal produced in accordance with the block address includes in address signal ADD, and the row selection is performed in the selected memory block. Since sub-memory array SMA is divided into the plurality of memory blocks MB0-MB7, each of sub-control circuits SCK0 and SCK1 is divided into local control circuits corresponding to memory blocks MB0-MB7.

As shown in FIG. 35, a block dividing operation or a partial activation is performed in sub-memory array SMA and the memory blocks in an unselected state are maintained in a precharged state for reducing a current consumption.

For arranging the sub-memory array shown in FIG. 35, sense amplifier band SAB8 of bank BA#1 and sense amplifier band SAB0 of bank BA#0 are arranged adjacently to each other on a boundary between banks BA#0 and BA#1. Thus, the sense amplifier band of each bank can be activated and deactivated independently of those of the other bank.

FIG. 36 schematically shows a structure for a portion related to sub-control circuits SCK0 and SCK1 shown in FIG. 34. Sub-memory array SMA2 included in bank BA#0includes memory blocks MB00-MB07. Sub-memory array SMA0 of bank BA#1includes memory blocks MB10-MB17. The sense amplifier bands are arranged on the opposite sides of these memory blocks MB00-MB07 and MB10-MB17 in the column direction. In FIG. 36, these sense amplifier bands are depicted as rectangular regions, respectively.

Sub-control circuit CKO includes local control circuits LCK00-LCK07 provided corresponding to memory blocks MB00-MB07, respectively, and sub-control circuit CKl includes local control circuits LCKIO-LCK17 provided corresponding to memory blocks MB10-MB17, respectively.

Main control circuit MCK produces a row-related control signal group BRC and a predecode block address signal PDA for the banks in accordance with externally applied command CMD and address signal ADD, and also produces internal clock signal CLK in accordance with an externally applied clock signal ECLK. Internal clock signal CLK generated from main control circuit MCK is applied commonly to local control circuits LCK00-LCK07 and LCK10-LCK17. Row-related control signal group BRC for the banks includes a row-related control signal BRO for bank BA#0 and a row-related control signal BR1 for bank BA-#. Row-related control signal BR0 is applied commonly to local control circuits LCK00-LCK07, and row-related control signal BRI is applied commonly to local control circuits LCK10-LCK17.

A predecode block address signal PBA is produced by predecoding a block address included in externally applied address signal ADD. Predecode block address signal PBA of 6 bits includes a predecode block address signal group PBG0 of 2 bits and a predecode block address signal group of 4 bits, and is applied commonly to banks BA#0 and BA#1. In FIG. 36, since each of banks BA#0 and BA#1includes eight memory blocks, the predecode block address of 6 bits is produced. Predecode block address group PBGO of 2 bits designates the memory blocks in an upper or lower half in each of banks BA#0 and BA#1. Predecode block address group PBG1 of 4 bits designates one memory block among these memory blocks in the upper half and the lower half in each of the banks. Therefore, each of local control circuits LCK00-LCK07 and LCK10-LCK17 receives one bit in each of these predecode block address bit groups PBG0 and PBG1.

Predecode block address signal PBA commonly designates the memory blocks in banks BA#0 and BA#1. In accordance with row-related control signal group BRC for the banks, the row-related control signals for the bank designated by the bank address included in address signal ADD is activated, and the operation related to row selection is performed in an activated bank.

For simplifying the figure, structures of sub-memory arrays SMA1 and SMA3 are not shown in FIG. 36. These sub-memory arrays SMA1 and SMA3 have structures similar to those of sub-memory arrays SMA0 and SMA2, and local control circuits LCK00-LCK07 and LCK10-LCK17 controls the row selecting operation therein.

Each of data paths DPA and DPB includes a write driver, a preamplifier and a data I/O buffer, and transmits data to and from the memory cells on a column selected by column decoder CDA.

As shown in FIG. 36, the row selection is performed on a block basis in each of banks BA#0 and BA#1, so that unselected memory blocks can be maintained in the precharged state, and the current consumption can be reduced.

The address signal (referred to as a “word line address signal”, hereinafter) for designating a word line must be applied commonly to all the memory blocks, or commonly to local control circuits LCK00-LCK07 and LCK10 and LCK17.

FIG. 37 shows an example of a structure of an input buffer in main control circuit MCK. Main control circuit MCK takes in externally applied command CMD and address signal ADD in synchronization with external clock signal ECLK (internal clock signal CLK). In FIG. 37, input buffer IB includes: an inverter IV that inverting clock signal (internal clock signal) CLK; a transmission gate XF1 that is turned on to pass input signal IN when clock signal CLK is at L-level; an inverter latch IL1 that latches the signal passing through transmission gate XF1; a transmission gate XF2 that is turned on to pass the signal latched by inverter latch IL when clock signal CLK is at H-level; and an inverter latch IL2 that latches the signal passing through transmission gate XF2 for producing an internal output signal OUT.

Transmission gates XF1 and XF2 are CMOS transmission gates, respectively, and are turned on/off in synchronization with clock signal CLK and a complementary clock signal generated from inverter IV. An operation of input buffer IB shown in FIG. 37 will now be described with reference to a signal waveform diagram shown in FIG. 38.

When clock signal CLK is at L-level, transmission gate XF1 is on, and inverter latch INi latches input signal IN. Meanwhile, transmission gate XF2 is off, and output signal OUT does not change.

When clock signal CLK rises to H-level, transmission gate XF1 is turned off, and input signal IN does not affect the latched signal of inverter latch IL. When clock signal CLK rises to H-level, transmission gate XF2 is responsively turned on, and the signal latched by inverter latch IL is transmitted to inverter latch IL2, so that output signal OUT is produced. Accordingly, output signal OUT changes in synchronization with the rising of clock signal CLK.

Input buffer IB shown in FIG. 37 is provided in main control circuit MCK for each of address signal ADD and command CMD. Internal signals are produced in synchronization with rising of clock signal CLK, and therefore the internal signals change in synchronization with the rising of clock signal CLK if a setup/hold time to clock signal CLK is ensured. Therefore, it is not necessary to consider a skew between these input signals, and it is possible to set timing for the internal operations faster.

FIG. 39 schematically shows line loads of the internal clock signal, row-related control signal and the predecode block address signal. In FIG. 39, internal clock signal CLK is transmitted by a clock driver DRV0 via a signal line SGL0. Row-related control signal BR (BR0 or BR1) is transmitted by a drive circuit DRV1 through a signal line SGL1. Predecode block address signal PB is transmitted by a drive circuit DRV2 via a signal line SGL2.

As shown in FIG. 36, the internal clock signal must be applied commonly to local control circuits LCK00-LCK07 and LCK10-LCK17 so that signal line SGL0 have the largest load capacitance C0.

As for the row-related control signal BR, since all the local control circuits of the corresponding bank are coupled, signal line SGL1 have a second largest load capacitance C1.

As for predecode block address signal PB, the local control circuits each for the two memory blocks are connected in each bank for predecode block address signal bit group PBG1 so that the signal lines for them has the smallest load capacitance C2. For predecode block address signal group PBG0, four local control circuits are connected in each bank. Therefore, a repeater may be arranged between the banks, whereby the load of the driver can be reduced, and the line load thereof can be made smaller than that for the row-related control signal. Since these signal lines SGL0-SGL2 have different line load capacitances C0-C2, their signal transmission delay times are different from each other, resulting in skews between signals. In particular, these signals are transmitted unidirectionally along the column direction from main control circuit MCK toward local control circuit LCK17 at the remotest position. Therefore, a difference in signal transmission delay time also occurs between local control circuit LCK00 nearest to main control circuit MCK and local control circuit LCK17 remotest therefrom, and therefore a difference occurs in magnitude of the skew between the both.

FIG. 40 schematic shows a timing relationship among the input signals of local control circuits LCK00 and LCK17 as well as the externally applied signals, i.e., clock signal ECLK, address signal ADD and command CMD.

Main control circuit MCK is supplied with external clock signal ECLK, address signal ADD and command CMD. In synchronization with rising of external clock signal ECLK, main control circuit MCK takes in externally applied address signal ADD and command CMD, and produces predecode block address signal PBA and row-related control signal BR (BR0 or BR1). For local control circuit LCK00 nearest to main control circuit MCK, the smallest difference occurs between internal clock signal CLK and external clock signal ECLK. Main control circuit MCK produces row-related control signal BR0 and predecode block address signal PBA in synchronization with internal clock signal CLK, for transmission to local control circuit LCK00.

In local control circuit LCK00, signal line SGL0 transmitting internal clock signal CLK has large interconnection capacitance C0, and internal clock signal CLK arrives at local control circuit LCK00 with a slight delay to arrival of predecode block address signal PBA and row-related control signal BR0. In this case, however, the interconnection lines of these signals are short so that a skew between predecode block address signal PBA and internal clock signal CLK is small. If local control circuit LCK00 performs an operation synchronized with internal clock signal CLK at the above described timing, the setup time of the predecode block address signal PBA is insufficient so that a malfunction may occur.

In local control circuit LCK17 remotest from main control circuit MCK, internal clock signal CLK is transmitted with the largest delay due to the long interconnection length. Likewise, the delay times of row-related control signal BR1 and predecode block address signal PBA are larger than that for local control circuit LCK00, but is smaller than that of internal clock signal CLK. In this case, a large phase difference occurs between predecode block address signal PBA and internal clock signal CLK, and thus a large skew occurs. In local control circuit LCK17, therefore, it is impossible to set a timing for starting an internal operation fast, and the fast operation is impossible.

The operation start timing in each local control circuit may be determined depending on the distance from main control circuit MCK. However, this complicates the circuit design. As external clock signal ECLK becomes fast, the timing adjustment time becomes an extremely short time, so that the timing adjustment must be performed extremely exactly. For the operation stability, the operation timing of the internal circuits may be determined in accordance with the worst skew conditions of local control circuit LCK17 remotest from main control circuit MCK. However, this makes the fast operation impossible.

In predecode block address signal PBA, predecode block address bit groups PBG0 and PBG1 have different line loads and different delay times. Therefore, the timing at which all the predecode block address bits are made definite differs for different local control circuits, and an accurate decoding may not be performed.

FIG. 41 shows schematically a structure of main control circuit MCK. In FIG. 41, main control circuit MCK includes: a clock buffer 900 which receives externally applied clock signal ECLK, and produces internal clock signal CLK; a command input buffer 902 which takes in externally applied command CMD in synchronization with internal clock signal CLK from clock buffer 900; a row address input buffer 904 which takes in externally applied address signal ADD in synchronization with internal clock signal CLK; a row-related control signal generating circuit 905 which decodes the command received from command input buffer 902 in synchronization with internal clock signal CLK, and produces a row-related control signal BR0 for bank BA#0 in accordance with the result of decoding; a row-related control signal generating circuit 906 which decodes the command received from command input buffer 902 in synchronization with internal clock signal CLK, and produces a row-related control signal BR1 for bank BA#1 in accordance with the result of decoding; and a column related control circuit 908 which decodes the command received from command input buffer 902 in synchronization with internal clock signal CLK, and controls the operation of circuits related to data access (column selection).

Row-related control signal generating circuits 905 and 906 receive a bank address BAD from row address input buffer 904, and activates the row-related signal generating circuit provided for the bank designated by bank address BAD. Row-related control signal BR0 for bank BA#0 includes a row address decode enable signal RADE<0>, a word line drive timing signal RXT<0>, a bit line isolation instructing signal BLI<0>, a bit line equalize instructing signal BLEQ<0> and sense amplifier activating signals SON<0> and SOP<0>. Likewise, row-related control signal BR1 for bank BA#1 includes the corresponding signals RADE<1>, RXT<1>, BLI<1>, BLEQ<1>, SON<1> and SOP<1>.

According to the configuration shown in FIG. 41, column-related control circuit 908 controls data path DP performing input/output of data. However, column-related control circuit 908 also controls the operation of column decoders provided for banks BA#0 and BA#1. Data path DP includes a write driver, a preamplifier, a data input buffer and a data output buffer.

As shown in FIG. 41, main control circuit MCK includes row-related control signal generating circuits 905 and 906 corresponding to banks B#0 and BA#1, respectively. For providing more banks, therefore, the row-related control signal generating circuits must be increased in number, and therefore, a layout of the row-related control signal generating circuits in main control circuit MCK must be changed. Therefore, main control circuit MCK must be re-designed depending on a bank configuration. When the load on the signal line changes in re-designing, further re-design is required for adjusting an inter-signal skew. Therefore, it is difficult to accommodate the change in bank structure. If the banks increase in number, the row-related control signal generating circuits increase in number, and the signal lines for transmitting the row-related control signals increase in number, so that the interconnection region and the area occupied by the circuits increase, and the chip size increases.

### SUMMARY OF THE INVENTION

An object of the invention is to provide a semiconductor memory device with an improved main control circuit, which can overcome the foregoing problems.

Another object of the invention is to provide a semiconductor memory device, which can be flexibly adapted to change in bank structure.

Still another object of the invention is to provide a semiconductor memory device, in which a skew between signals does not change regardless of a position of a memory block.

Yet another object of the invention is to provide a semiconductor memory device, which can reduce a signal interconnection area.

Further another object of the invention is to provide a semiconductor memory device of a multi-bank structure, which has a reduced chip size, and can operate stably.

A further object of the invention is to provide a semiconductor memory device, which can suppress increase in area of interconnections for main control signals even if banks increase in number.

A still further object of the invention is to provide a semiconductor memory device, in which a structure of main control circuit is independent of a bank configuration.

A semiconductor memory device according to the present invention includes: a main control circuit for producing a plurality of main control signals having different phases from each other in response to a row-related instructing signal for instructing an operation related to row selection; and a sub-control circuit receiving the plurality of main control signals, for producing sub-control signals greater in number than the plurality of main control signals. These sub-control signals are signals for controlling an operation instructed by the row-related instructing signal.

The plurality of main control signals are produced in accordance with the row-related instructing signal, and these main control signals having different phases are converted into the sub-control signals by the sub-control circuit. Thus, it is not necessary to generate a large number of signals by the main control circuit, and control signal lines between the main control circuit and the sub-control circuit can be reduced in number. Accordingly, the area occupied by the signal interconnection lines can be reduced.

These main control signals are produced merely in accordance with the row-related instructing signal, and the main control signal common to the plurality of banks can be produced. Neither the reduction in interconnection area nor the change in bank number and structure requires the change in structure of the main control circuit, so that it is possible to cope with the change in bank configuration flexibly.

With the main control signal and an address signal equal in line load, signal transmission delay of each signal line can be made equal to those of other signal lines, and a skew between signals can be reduced. Even if a signal transmission delay occurs, the delay of signal in each subcontrol circuit can be equal to that in other sub-control circuits, and the skews between signals in the sub-control circuits can be equal to each other. Therefore, the signal timing can be easily adjusted, and the semiconductor memory device capable of stable operation can be achieved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 schematically shows a structure of a main portion of a semiconductor memory device according to a first embodiment of the invention;

FIG. 2 schematically shows a structure of a semiconductor integrated circuit device including a semiconductor memory device according to the invention;

FIG. 3 shows more specifically a structure of a main control circuit and a local control circuit shown in FIG. 1;

FIG. 4 is a signal waveform diagram representing an operation of the circuits shown in FIG. 3;

FIG. 5 shows more specifically a structure of a sense amplifier and a memory block shown in FIG. 3;

FIG. 6 schematically shows a structure of an output portion of the main control circuit and an input portion of the local control circuit in the first embodiment of the invention;

FIG. 7 is a signal waveform diagram representing an operation of the structure shown in FIG. 6;

FIG. 8 shows an example of a structure of an address input circuit shown in FIG. 3;

FIGS. 9A-9C schematically illustrate an effect of the structure shown in FIG. 6;

FIG. 10A shows a structure of a main row activation control circuit shown in FIG. 3, and FIG. 10B is a signal waveform diagram representing an operation of the circuit shown in FIG. 10A;

FIG. 11A shows a modification of the main row activation control circuit, and FIG. 11B is a signal waveform diagram representing an operation of the circuit of FIG. 11A;

FIG. 12A shows a structure of a main precharge control circuit shown in FIG. 3, and FIG. 12B is a signal waveform diagram representing an operation of the circuit shown in FIG. 12;

FIG. 13A shows a modification of the main precharge control circuit, and FIG. 13B is a signal waveform diagram representing an operation of the circuit of FIG. 13A;

FIG. 14 schematically illustrates an effect of the structures shown in FIGS. 10A and 12A;

FIG. 15A shows a structure of a delay circuit shown in FIG. 12, and FIG. 15B shows a modification of a delay value setting circuit shown in FIG. 15A;

FIG. 16 shows a structure of a second modification of the delay value setting circuit shown in FIG. 15A;

FIG. 17 shows a structure of a third modification of the delay value setting circuit shown in FIG. 15A;

FIG. 18 shows a structure of a local control circuit shown in FIG. 3;

FIG. 19 is a signal waveform diagram representing an operation of a circuit shown in FIG. 18;

FIG. 20 shows signal waveforms in high speed operation of the circuit shown in FIG. 18;

FIG. 21 shows a structure of a block address decoder shown in FIG. 3;

FIG. 22 shows a structure of a first modification of the block address decoder shown in FIG. 21;

FIG. 23 shows a structure of a select circuit shown in FIG. 22;

FIG. 24 schematically shows a structure of a second modification of a block address decoder shown in FIG. 21;

FIG. 25 shows a structure of a third modification of a block address decoder shown in FIG. 24;

FIG. 26 shows a sequence for generating a plurality of main control signal sets;

FIG. 27 schematically shows a structure of a main control circuit implementing an operation sequence shown in FIG. 26;

FIG. 28A shows a structure of an ACT counter shown in FIG. 27, FIG. 28B shows a structure of a latch 92 shown in FIG. 28A, and FIG. 28C shows a structure of a latch 93 shown in FIG. 28A;

FIG. 29 shows a structure of a main row activating signal generating circuit shown in FIG. 27;

FIG. 30 schematically shows a structure of a main precharge control circuit corresponding to the structure shown in FIG. 27;

FIG. 31 shows an example of a structure of a PRC counter shown in FIG. 30;

FIG. 32 shows a structure of a local control circuit corresponding to the structure shown in FIG. 27;

FIG. 33 shows another embodiment of the local control circuit;

FIG. 34 schematically shows a whole structure of a conventional semiconductor memory device in the prior art;

FIG. 35 schematically shows a structure of a sub-memory array shown in FIG. 34;

FIG. 36 schematically shows signal lines of a main control circuit and local control circuits of a semiconductor memory device in the prior art;

FIG. 37 shows a structure of an input buffer circuit in the semiconductor memory device in the prior art;

FIG. 38 is a signal waveform diagram showing an operation of the input buffer circuit shown in FIG. 37;

FIG. 39 schematically shows signal line loads of the semiconductor memory device;

FIG. 40 is a signal waveform diagram representing an operation on signal lines shown in FIG. 39; and

FIG. 41 schematically shows a structure of a main control circuit of the conventional semiconductor memory device.

### DESCRIPTION OF THE PREFERRED EMBODIMENTS

First Embodiment

FIG. 1 schematically shows a structure of a main portion of a semiconductor memory device according to a first embodiment of the invention. For memory blocks MBa-MBn, there are provided row-related circuits 15a-15n, respectively. Each of row-related circuits 15a-15n includes a sense amplifier circuit, a bit line isolating circuit, a bit line precharge/equalize circuit and others. More specifically, each of row-related circuits 15a-15n executes an operation related to a row selection in corresponding one of memory blocks MBa-MBn when made active. Also, each of row-related circuits 15a-15n drives the corresponding one of memory blocks MBa-MBn to the precharged state when made inactive.

Local control circuits 10a-10n are provided for row-related circuits 15a-15n, respectively. Each of these local control circuits 10a-10n is activated in accordance with a block select signal (not shown), and produces a local row control signal group RSELG for corresponding one of row-related circuits 15a-15n when made active. Local row control signal group RSELG includes q row control signals. The row control signals included in local row control signal group RSELG will be described later in greater detail.

A main control circuit 1 is provided commonly to these local control circuits 10a-10n. Main control circuit 1 produces a group of a plurality of main row control signals MRCTLG having different phases from each other when it receives a row-related command ROWCOM, and transmits the generated signals via a control signal bus 2. This main row control signal group MRCTLG includes p control signals, with p smaller than the number q of row control signals included in local row control signal group RSELG.

As described above, main control circuit 1 produces and transmits the plurality of main control signals having different phases onto control signal bus 2 when it receives a row-related command ROWCOM instructing an operation related to selection/deselection of a row. Main row control signal group MRCTLG is independent of the address signal. Local control circuits 10a-10n produces, when selected, local row control signal group RSELG greater in number than main row control signal group MRCTLG, in accordance with main row control signal group MRCTLG. Therefore, if the load on control signal bus 2 is large, the number of control signal lines can be reduced so that the current consumption and interconnection area can be reduced. Further, main row control signal group MRCTLG is independent of an address, and therefore it is not necessary to change the structure of main control circuit 1 even when the banks increase in number. In this case, addition of the local control circuit is merely required, and it is easy to be adapted to the change in bank configuration.

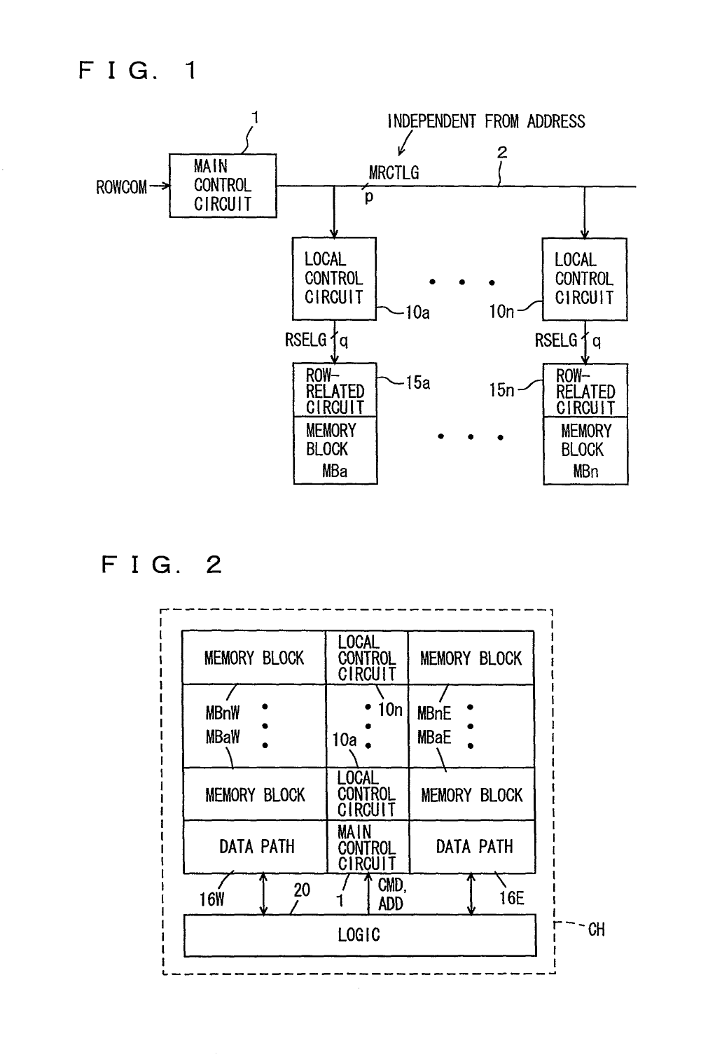

FIG. 2 schematically shows a structure of a semiconductor integrated circuit device including the semiconductor memory device according to the present invention. In a semiconductor integrated circuit device CH shown in FIG. 2, the semiconductor memory device is mounted together with a logic 20, which performs predetermined processing and data access to this semiconductor memory device, on a common semiconductor chip. The semiconductor memory device includes a plurality of memory blocks MBaW-MBnW and MBaE-MBnE, local control circuits 10a-10n arranged corresponding to memory blocks MBaW and MBaE to MBnW and MBnE, respectively, a main control circuit 1 which receives a command CMD and an address ADD from logic 20, to produce main row-related control signals for local control circuits 10a-10n, a data path 16W provided for memory blocks MBaW-MBnW, and a data path 16E provided for memory blocks MBaE-MBnE. Each of data paths 16W and 16E includes a data input buffer, a data output buffer, a write driver for producing internal write data and a preamplifier for producing internal read data, and transmits data to and from logic 20.

As shown in FIG. 2, the layout of a whole of the semiconductor memory device itself is substantially the same as that of a conventional device. However, configuration of row-related control signals transmitted from main control circuit 1 to local control circuits 10a-10n is different from that in the conventional device, and therefore the structures of local control circuits 10a-10n are also different from the conventional structure. Specific structures will now be described.

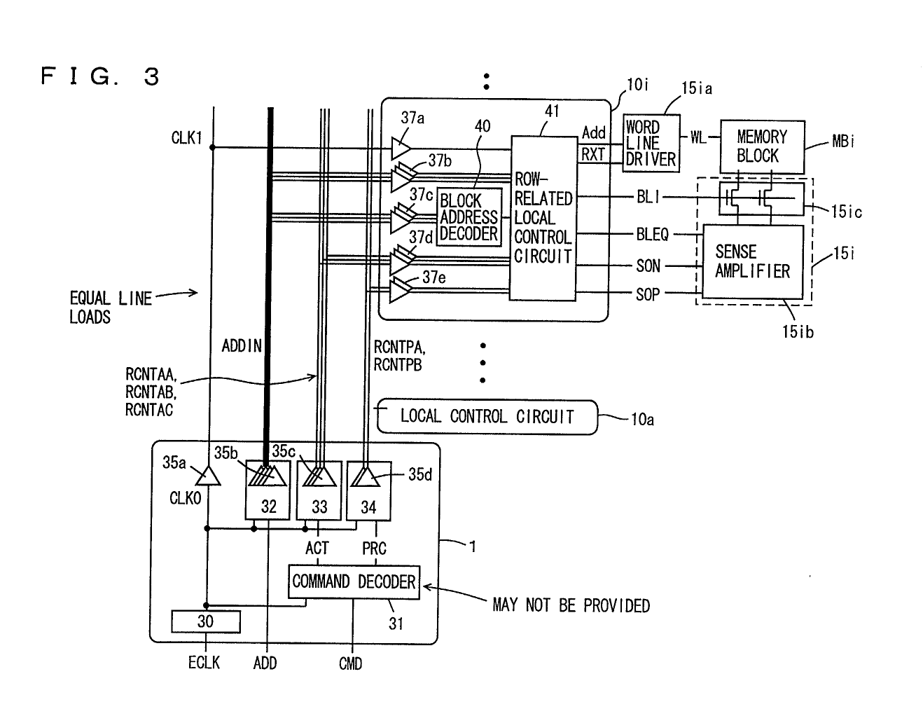

FIG. 3 schematically shows row-related control circuit portions in the main and local control circuits. In FIG. 3, main control circuit 1 includes a clock input buffer 30 that receives a clock signal ECLK from the logic, to produce an internal clock signal CLK0, a command decoder 31 that takes in and decodes command CMD sent from the logic in synchronization with internal clock signal CLK0 received from clock input buffer 30, for selectively activating and deactivating a row active signal ACT and a precharge instructing signal PRC, a clock driver 35a that receives internal clock signal CLK0 generated from clock input buffer 30, to transmit an internal clock signal CLK1 to local control circuits 10a-10n, an address input buffer 32 that takes in address signal ADD to produce an internal address signal ADDIN in synchronization with internal clock signal CLK0, a main row activation control circuit 33 that receives row active signal ACT from command decoder 31, to produce signals of three phases, i.e., main row activating signals RCNTAA, RCNTAB and RCNTAC, and a main precharge control circuit 34 that receives a precharge instructing signal PRC generated from command decoder 31 in synchronization with internal clock signal CLK0 to produce signals of two phases, i.e., main precharge activating signals RCNTPA and RCNTPB.

These internal signals CLK1, RCNTAA, RCNTAB RCNTAC, RCNTPA, RCNTPB, and ADDIN are transmitted through internal signal transmission lines that are the same in interconnection line and in line impedance.

Each of address input buffer 32, main row activation control circuit 33 and main precharge control circuit 35 has a drive circuit for its output signal. All of the drive circuits have the same structure (same transistor size), and drive the corresponding signals to local control circuits 10a-10n with the same driving capability. The internal signal transmission lines are the same in line impedance, and therefore, the internal signals CLK1, RCNTAA, RCNTAB RCNTAC, RCNTPA, RCNTPB, and ADDIN are transmitted at the same rate with the same driving capability of the drivers 35a-35d to the respective local control circuits 10a-10n, and the timing skew of the internal signals can be eliminated at each of the local control circuits 10a-10n.

Each of local control circuits 10a-10n have the same structure, and FIG. 3 schematically shows an internal structure of local control circuit 10i as a representative. Local control circuit 10i includes: a clock input circuit 37a for receiving internal clock signal CLK1, an address input circuit 37b for receiving internal address signal ADDIN; an input circuit 37d for receiving main row activating signals RCNTAA-RCNTAC; an input circuit 37e for receiving main precharge control signals RCNTPA and RCNTPB; a block address decoder 40 for receiving and decoding the block address signal generated from address input circuit 37c; and a row-related local control circuit 41 for producing row-related control signals BLI, BLEQ, SON, SOP and RXT as well as a word line select signal Add in accordance with the block select signal generated from block address decoder 40, the internal clock signal generated from clock input circuit 37a and the output signals of input circuits 37d and 37e.

Input circuits 37a-37e include buffer circuits having the same structure, and have the same input load (input impedance). Therefore, all the drive loads of drivers 35a-35d of main control circuit 1 are equal to each other, and each signal transmitted from main control circuit 1 to the local control circuit is associated with equal line loads for all the memory blocks. Therefore, skews between the signals for the individual memory blocks can be equal to each other.

Memory block MBi is provided for local control circuit 10i. As a row-related circuit 15i for memory block MBi, there are provided a word line driver 15ia, a sense amplifier 15ib and a bit line isolating circuit 15c. Word line driver 15ia drives a word line WL corresponding to an addressed row in memory block MBi in accordance with word line select signal Add and word line drive timing signal RXT generated from row-related local control circuit 41.

Bit line isolating circuit 15c includes bit line isolating gates provided corresponding to respective bit line pairs in memory block MBi, and isolates sense amplifier 15ib and memory block MBi from each other when bit line isolation instructing signal BLI is at L-level. Sense amplifier 15ib includes sense amplifier circuits provided corresponding to the bit line pairs and bit line precharge/equalize circuits provided corresponding to the bit line pairs. Bit line equalize instructing signal BLEQ is applied to bit line equalize/precharge circuit for precharging and equalizing each bit line pair to an intermediate voltage level. Sense amplifier activating signals SON and SOP selectively activate and deactivate the sense amplifier circuits included in sense amplifier 15ib.

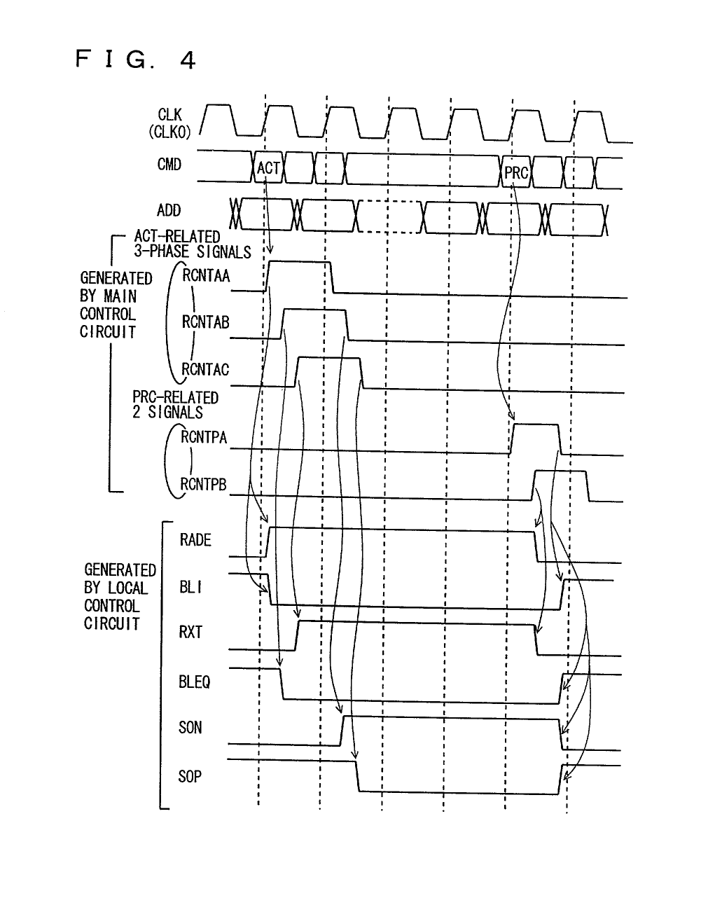

Operations of the main and local control circuits shown in FIG. 3 will now be described with reference to a signal waveform diagram shown in FIG. 4.

In main control circuit 1, command decoder 31 takes in command CMD, which is externally applied, e.g., from the logic, at the rising edge of internal clock signal CLK0, and produces a signal instructing an operation mode designated by the command taken. In the case of row active command, i.e., in the case where command CMD instructs the row selection, command decoder 31 activates row active signal ACT. Main row activation control circuit 33 is responsive to the activation of row active signal ACT, for producing main row activating signals RCNTAA, RCNTAB and RCNTAC of three phases, which rise and fall at different timings.

In local control circuit 10i, block address decoder 40 decodes the block address included in the address signal, and produces the block select signal (block hit signal) indicating a result of this decoding. When the block select signal is active, row-related local control circuit 41 activates sequentially the row-related control signals in response to the edges of the main row activating signals. More specifically, row-address decode enable signal RADE is activated in response to the rising of main row activating signal RCNTAA, and bit line isolation instructing signal BLI also attains L-level in response to the rising of main row activating signal RCNTAA. By this falling of bit line isolation instructing signal BLI to L-level, a memory block paired with the selected memory block is isolated from the sense amplifier (band).

Then, bit line equalize instructing signal BLEQ falls to L-level in response to the rising of main row activating signal RCNTAB, and the operation of equalizing and precharging the bit lines stops.

Then, word line drive timing signal RXT is activated in response to the rising of main row activating signal RCNTAC. In accordance with word line drive timing signal RXT, word line driver 15ia is activated to drive, to the selected state, an addressed word line in accordance with word line select signal Add produced through decoding in response to the activation of row address decode enable signal RADE.

Then, sense amplifier activating signal SON rises to H-level in response to the falling of main row activating signal RCNTAB, and sense amplifier activating signal SOP lowers to L-level in response to the falling of main row activating signal RCNTAC. Responsively, sense amplifier 15ib is activated to sense, amplify and latch the data of memory cells connected to the selected word line. These signals RADE, BLI, RXT, BLEQ, SON and SOP maintain the current states until a precharge command instructing the end of row selection is applied subsequently.

When a precharge command for driving the selected memory block to the unselected state is applied as command CMD, command decoder 31 drives the precharge instructing signal PRC to the active state. Responsively, main precharge control circuit 34 produces main precharge control signals RCNTPA and RCNTPB of two phases in accordance with precharge instructing signal RPC and in synchronization with internal clock signal CLK0. These main precharge control signals RCNTPA and RCNTPB rise and fall with different phases. In response to the rising of main precharge control signal RCNTPB, row address decode enable signal RADE and word line drive timing signal RXT fall to L-level, and the selected word line is driven to the unselected state.

Then, in response to the falling of main precharge control signal RCNTPA, bit line isolation instructing signal BLI attains H-level, and bit line equalize instructing signal BLEQ attains H-level. Responsively, the paired, unselected memory block is connected to the sense amplifier band, and the bit line precharge/equalize circuit is activated in the sense amplifier, so that each bit line is precharged and equalized to the predetermined intermediate voltage. Further, sense amplifier activating signals SON and SOP attain L-and H-levels, respectively, in response to the fall of main precharge control signal RCNTPA, and the sense amplifier circuits are deactivated.

Therefore, it is possible to produce more local row-related control signals required for the row-related circuits by combining the phases of the control signals of the row-related local control circuits. Thereby, it is possible to reduce the number of control signal lines, having a large line load, for transmitting the row-related control signals from the main control circuit to the local control circuit. Therefore, the charge/discharge currents on the transmission lines can be reduced, and the current consumption can be reduced. Further, the main row activating signals transmitted from main control circuit 1 to local control circuits 10a-10n can be reduced in number, and thus the line-occupying area can be reduced.

In the above discussion, the local row-related control signals are of six types, and three phase main row control signals are generated. However, if the local row-related control signals are of four types, only the two phase main row control signals needs to be generated because four edges of the main row control signals can be assigned to the respective local row-related control signals of four types. Therefore, the number of phases of the main row control signals is appropriately determined according to the number of the local row-related control signals to be generated. The condition that main row control signals of M phases are produced to generate local row-related control signals of N types at different timings, where M<N, and 2M≧N.

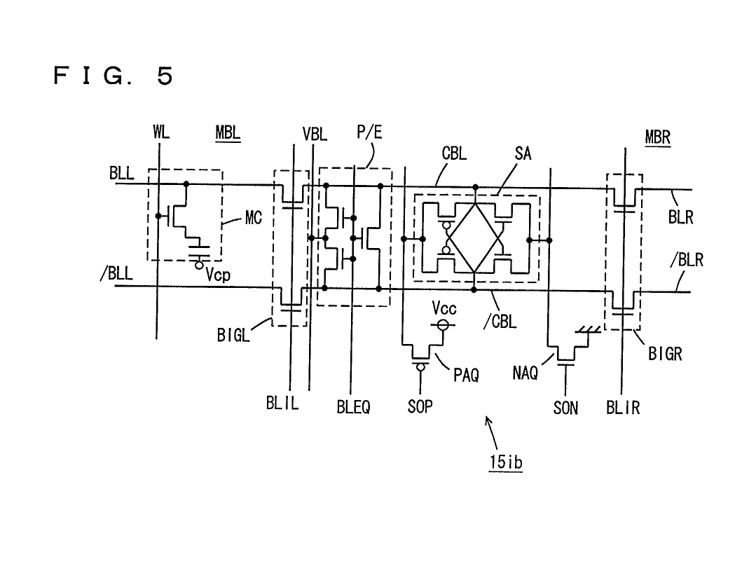

FIG. 5 shows more specifically the structure of the sense amplifier portion shown in FIG. 3. FIG. 5 shows the structure of the sense amplifier circuit included in the sense amplifier between two memory blocks MBL and MBR, and provided for one bit line pair. In FIG. 5, sense amplifier 15ib includes: a precharge/equalize circuit P/E which precharges and equalizes common bit lines CBL and /CBL to an intermediate voltage VBL in response to bit line equalize instructing signal BLEQ; a sense amplifier circuit SA which differentially amplifies and latches the potentials on common bit lines CBL and /CBL when made active; a sense amplifier activating transistor PAQ which transmits a power supply voltage Vcc to sense amplifier circuit SA in accordance with sense amplifier activating signal SOP; and a sense amplifier activating transistor NAQ which transmits a ground voltage to sense amplifier circuit SA in response to activation of sense amplifier activating signal SON. Sense amplifier circuit SA includes cross-coupled P-channel MOS transistors (insulated gate field effect transistors) and cross-coupled N-channel MOS transistors.

Common bit lines CBL and /CBL are connected to bit lines BLL and /BLL via a bit line isolating gate BIGL, and is also connected to bit lines BLR and /BLR via bit line isolating gate BIGR. Bit line isolating gate BIGL is made conductive when bit line isolation instructing signal BLIL is at H-level, and bit line isolating gate BIGR is made conductive when bit line isolation instructing signal BLIR is at H-level. The bit lines in a selected memory block are connected to common bit lines CBL and /CBL, and the unselected memory block that is paired with the selected memory block, is isolated from common bit lines CBL and /CBL.

In memory block MBL, a memory cell MC is arranged corresponding to a crossing between word line WL and bit line BL. Although not shown clearly, memory cell MC is arranged corresponding to a crossing between word line WL and one of bit lines BL and /BL. In a similar manner, the memory cells are arranged in memory block MBR as well.

In the structure shown in FIG. 5, bit line precharge/equalize circuit P/E may be arranged corresponding to each of the pair of bit lines BLL and /BLL and the pair of bit lines BLR and /BLR in respective memory blocks MBL and MBR.

One pair of sense amplifier activating transistors PAQ and NAQ are generally provided for a predetermined number of sense amplifier circuits SA.

According to the first embodiment of the invention, as described above, the main control circuit produces a plurality of main control signals having different phases in accordance with a row-related command, and transmits the generated main control signals to the local control circuits. The local control circuit in turn produces the row-related operation control signal required for executing a designated row-related operation in accordance with the plurality of main control signals. Therefore, the main control signal lines with large line loads can be reduced in number, and the current consumption and the line-occupying area can be reduced.

In the structure shown in FIG. 3, main control circuit 1 includes command decoder 31 for decoding command CMD externally applied, e.g., from the logic. However, the logic may be configured to apply an operation mode instructing signal which is already decoded. In this case, command decoder 31 is not required particularly.

Second Embodiment

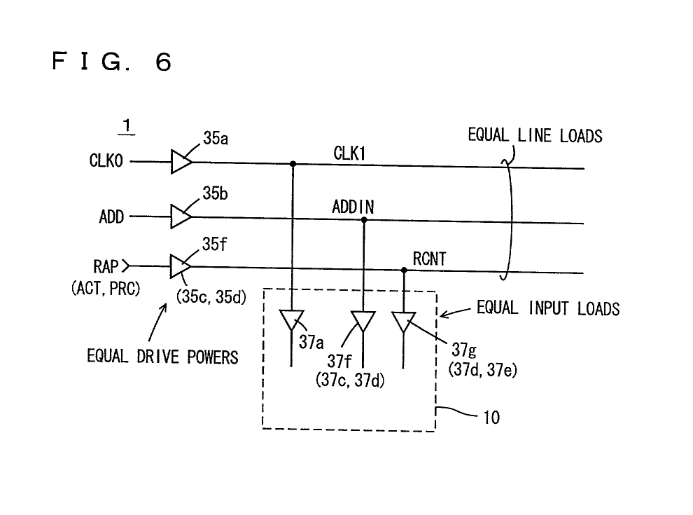

FIG. 6 schematically shows a structure of a main portion of a second embodiment according to the present invention. FIG. 6 shows an output portion of the main control circuit and an input portion of the local control circuit. In main control circuit 1 shown in FIG. 6, driver 35a transmits clock signal CLK0 as internal clock signal CLK1 to local control circuit 10 (10a-10n). Driver 35b transmits address signal ADD as internal address signal ADDIN to local control circuits 10 (10a-10n).

The main control signal produced from row-related operation instructing signal RAP (ACT and PRC) is transmitted commonly to local control circuits 10 (10a-10n) as row-related control signal RCNT by drivers 35f (35c, 35d). These drivers 35a, 35b and 35f have the same drive capability, and these signals CLK1, ADDIN and RCNT are transmitted by the same driving capability.

In local control circuit 10, input circuit 37a receives internal clock signal CLK1, input circuit 37f (37c, 37d) receives internal address signal ADDIN, and input circuit 37g (37d, 37e) receives row-related control signal RCNT. These input circuits 37a, 37c and 37e have the same input load (input impedance) due to the same transistor size. Accordingly, all the loads of signals CLK1, ADDIN and RCNT are equal to each other. All the loads of the signal lines for respective signals are equal to each other, and the skew between the signals can be uniform in the respective memory blocks, so that stable operations can be achieved.

These signal interconnection lines are made equal in length owing to an appropriate layout. The interconnection lengths may slightly vary depending on the positions of the circuits in the main control circuit. However, the interconnection lines arranged over the whole local control circuits 10a-10n each have a large length of about, e.g., several millimeters. Thus, the difference in interconnection length in the main control circuit is only to an negligible extent, and the loads of interconnection lines for the respective signals can be made equal to each other.

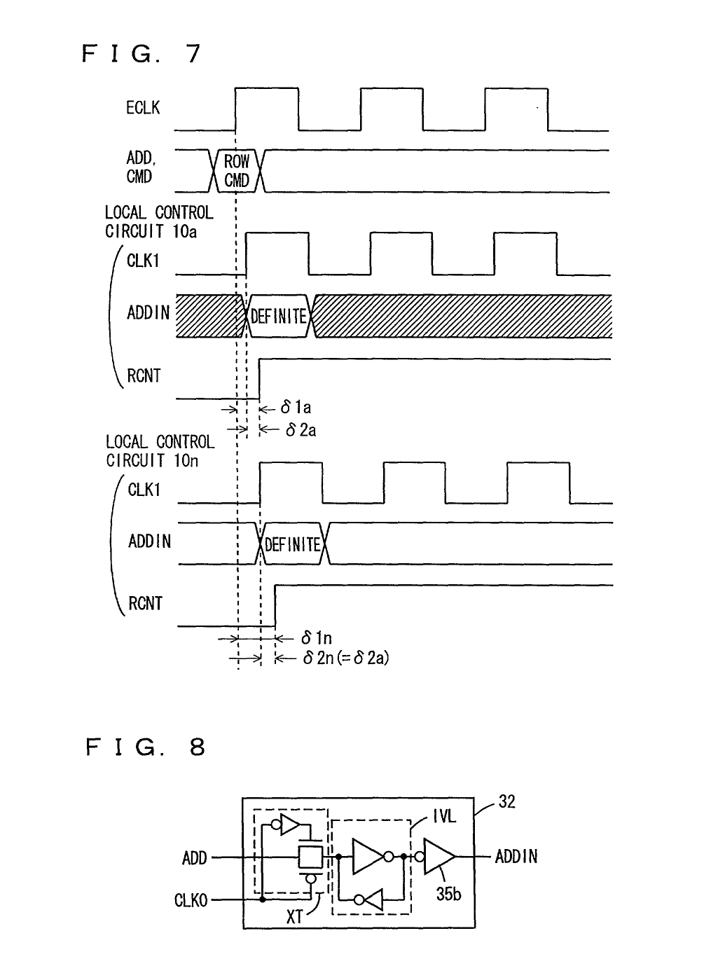

FIG. 7 is a signal waveform diagram representing signal transmission in the structure shown in FIG. 6.

At the rising of external clock signal CLK, command CMD and address signal ADD are taken into the main control circuit, and are transmitted by the circuits 32, 33 and 34 shown in FIG. 3 to the inputs of each respective local control circuit.

Since local control circuit 10ais nearest to main control circuit 1, the delay time of internal clock signal CLK1 with respect to external clock signal ECLK is the smallest. Since internal address signal ADDIN is produced in accordance with internal clock signal CLK1, and is transmitted via driver 36b, the delay of internal address signal ADDIN with respect to internal clock signal CLK1 is also small.

Likewise, row-related control signal RCNT is transmitted to local control circuit 10 via driver 35f. An operation of internally producing control signals of different phases is required. This row-related control signal RCNT has a delay time δ2a with respect to internal address signal ADDIN, and row-related control signal RCNT has a delay time δ1a with respect to external clock signal ECLK.

In local control circuit 10n remotest from main control circuit 1, internal clock signal CLK1 arrives with a further delay to external clock signal ECLK. However, internal address signal ADDIN is transmitted with the same load as that for internal clock signal CLK1. Therefore, the relationship in timing between internal clock signal CLK1 and internal address signal ADDIN can be the same in local control circuits 10n and 10a. Further, row-related control signal RCNT is transmitted to local control circuit 10n with a larger signal transmission delay (due to its large interconnection length), as compared with local control circuit 10a. However, internal address signal ADDIN and row-related control signal RCNT are transmitted by drivers 35b and 35f having the same drive capability, and are applied to the circuits of the same input load. Therefore, a skew δ2n between these signals of the local control circuit 10n is the same as skew 62a of local control circuit 10a.

Thus, signal transmission delays occur in local control circuits 10a-10n, respectively, but all the skews between the signals are uniform so that the control signals and address signals are applied to the local control circuits with the same timing relationship. Even if local control circuits 10a-10n operate in accordance with internal clock signal CLK1 and in accordance with row-related control signal RCNT, the internal operations can be performed in all the local control circuits with the same timing relationship. Thus, the same setup/hold time conditions are satisfied in all the local control circuits, so that accurate operations can be ensured.

FIG. 8 shows an example of the structure of address input buffer 32 shown in FIG. 3. In FIG. 8, address input buffer 32 includes: a transmission gate XT which takes in address signal ADD in response to the rising of internal clock signal CLK0; an inverter latch IVL which latches the signal taken in by transmission gate XT; and a driver 35b which buffers the signal latched by inverter latch IVL, and transmits the buffered signal as internal address signal ADDIN to each local control circuit.

In address input buffer 32 shown in FIG. 8, transmission gate XT is conductive when internal clock signal CLK0 is at L-level. When internal clock signal CLK0 is at H-level, transmission gate XT is non-conductive. Thus, internal address signal ADDIN changes in accordance with externally applied address signal ADD when internal clock signal CLK0 is at L-level. When internal clock signal CLK0 is at H-level, internal address signal ADDIN is in the definite state. Therefore, internal address signal ADDIN is in the definite state when internal clock signal CLK1 rises. In the operation of decoding the address signal in local control circuit 10, therefore, the address signal ADDIN is already in the definite state when the decoding operation starts in response to the rising of internal clock signal CLK1, strictly, in response to row address decode enable signal RADE. Therefore the decoding operation can be performed accurately.

Since the line loads for the respective signals are equal to each other, the row selecting operation can be performed accurately in each memory block even in the case where the line load is large.

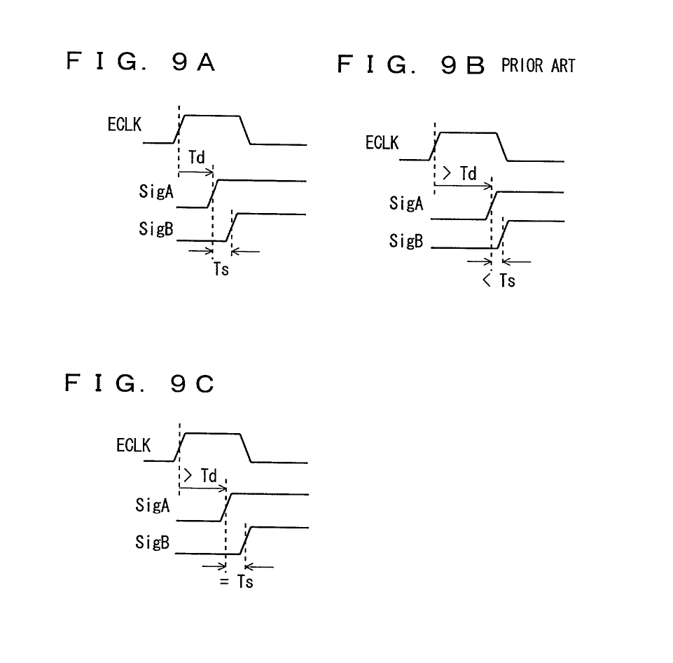

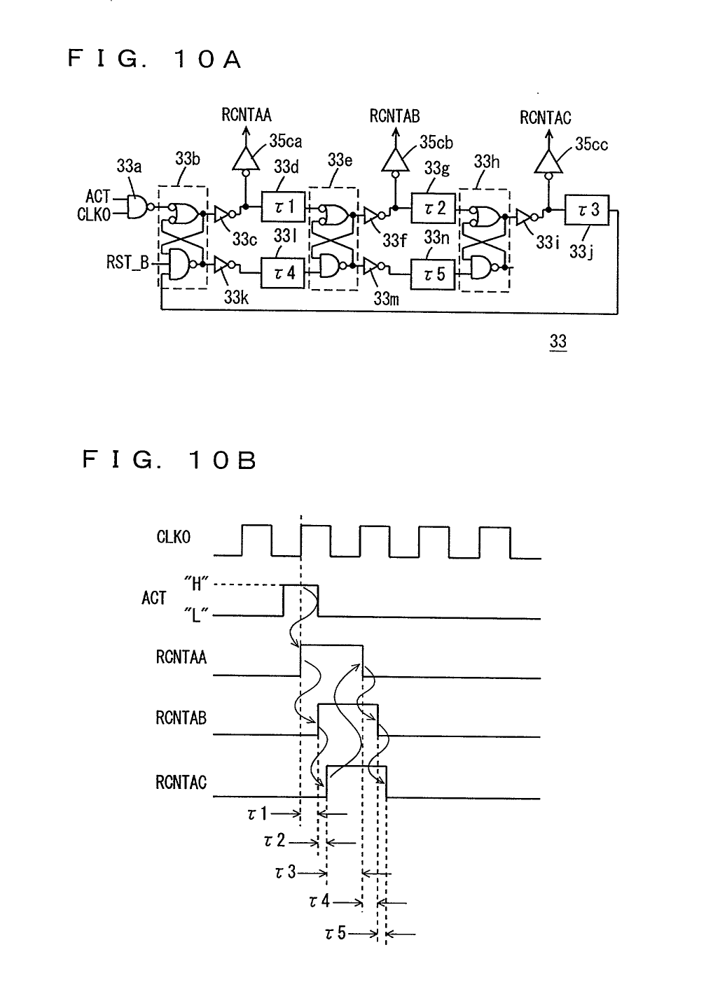

The description will now be given on the case where a time difference (setup time) of Ts is present between two signals SigA and SigB, as shown in FIG. 9A. In this case, signal SigA has a delay time Td with respect to external clock signal CLK. In this state, if the memory blocks are increased in number, and therefore a bank expansion is performed, loads of signals SigA and SigB change. In the prior art, as shown in FIG. 9B, loads of signals SigA and SigB are different from each other. Therefore, the transmission delay time of signal SigA is longer than delay time Td achieved before the expansion, and the time difference between signals SigA and SigB becomes shorter, so that a setup time failure occurs, and accurate operation cannot be ensured. Accordingly, re-designing is required when the memory blocks increase in number to increase the loads of signal lines.

In contrast, the loads of all the signals are equal to each other according to the present invention. In this case, as shown in FIG. 9C, the delay time of signal SigA with respect to external clock signal ECLK is longer than original delay time Td, but the time difference (setup time difference) between signals SigA and SigB is equal to the original time Ts. Therefore, even in the case where the number of banks or memory blocks increases and therefore the loads of signals increase, the timing relationship between these signals SigA and SigB can be maintained. Accordingly, change in memory array structure does not require re-designing of the main control circuit.

According to the second embodiment of the present invention, as described above, the loads of signals transmitted from the main control circuit to the local control circuits are all made equal to each other. Therefore, the signal transmission delays can be made equal to each other for each signal, and the skews between the signals can be constant in all the memory blocks independently of the positions of the memory blocks so that stable operations can be ensured. Even when the array structure is changed, e.g., for bank expansion, the conditions that all the loads of signals are equal are maintained. Therefore, the timing relationship between the signals can be maintained even after change in array structure, and the stable operations can be ensured.

The local control circuits are provided corresponding to the memory blocks, respectively. In this case, each local control circuit can be operated as a bank control circuit.

Third Embodiment

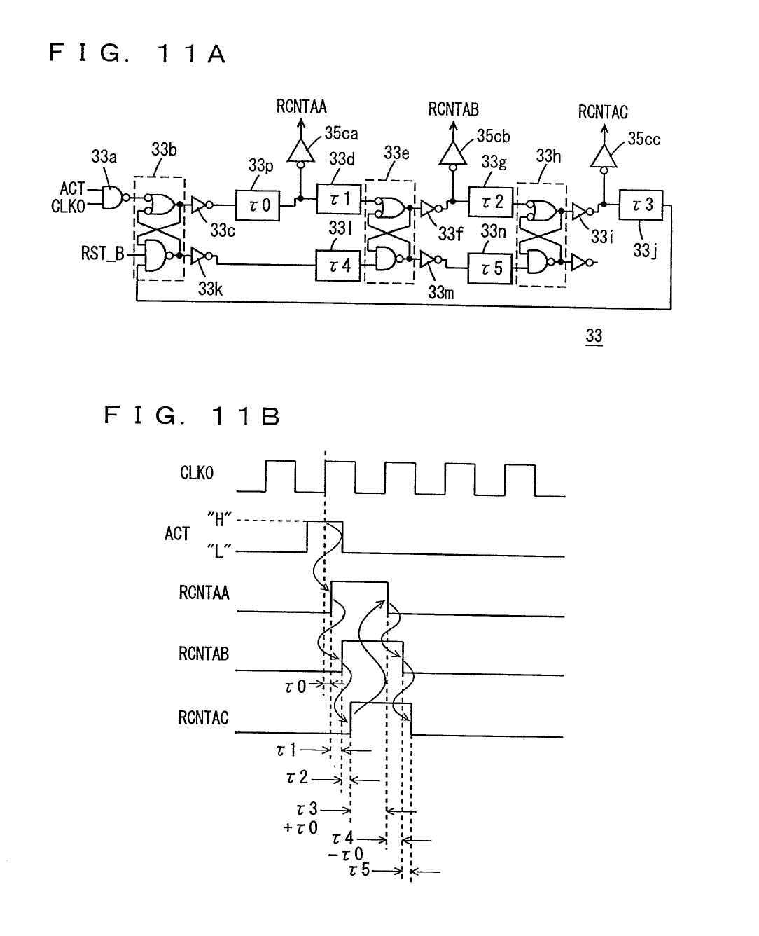

FIG. 10A shows a structure of main row activation control circuit 33 according to a third embodiment of the invention. In FIG. 10A, main row activation control circuit 33 includes: an NAND circuit 33a which receives row active signal (or command) ACT and internal clock signal CLK0; a set/reset flip-flop 33b which is set to generate a signal of an active state (H-level) at its first output when the output signal of NAND circuit 33a is at L-level; an inverter 33c which inverts the signal on the first output of set/reset flip-flop 33b; a driver 35ca which receives the output signal of inverter 33c and produces main row activating signal RCNTAA; a delay circuit 33d which delays the output signal of inverter 33 by a time τ1; a set/reset flip-flop 33e which is reset to drive the signal on a first output thereof to H-level when the output signal of delay circuit 33d is at L-level; an inverter 33f which inverts the signal on the first output of set/reset flip-flop 33e; a driver 35cb which inverts the output signal of inverter 33f to produce main row activating signal RCNTAB; a delay circuit 33g which delays the output signal of inverter 33f by a time τ2; a set/reset flip-flop 33h which is set to generate a signal of H-level at its first output when the output signal of delay circuit 33g is at L-level; an inverter 33i which inverts the signal on the first output of set/reset flip-flop 33h; and a driver 35cc which inverts the output signal of inverter 33i to produce main row activating signal RCNTAC.

With delay circuits 33d and 33g, main row activating signal RCNTAB is activated after time τ1 from activation of main row activating signal RCNTAA, and main row activating signal RCNTAC is activated after time τ2 from activation of main row activating signal RCNTAB. In response to activation of row active signal ACT, main row control signals RCNTAA-RCNTAC, which rise with different phases, can be produced. Drivers 35ca-35cb have the equal drive capability.

Main row activation control circuit 33 further includes: a delay circuit 33j which delays the output signal of inverter 33a by a time τ3, and resets set/reset flip-flop 33d; an inverter 33k which inverts the signal on a second output of set/reset flip-flop 33b; a delay circuit 33l which delays the output signal of inverter 33k by a time τ4, and resets set/reset flip-flop 33e; an inverter 33m which inverts the signal on a second output of set/reset flip-flop 33l; and a delay circuit 33n which delays the output signal of inverter 33m by a time τ5 for application to a second input of set/reset flip-flop 33h.

When the output signal of delay circuit 33n attains L-level, set/reset flip-flop 33h is reset. When the output signals of delay circuits 33j and 33l attain L-level, set/reset flip-flops 33b and 33e are reset. Set/reset flip-flop 33b in the initial stage is supplied with a system reset signal RST_B. System reset signal RST_B is driven to L-level of the active state upon power-on or system reset. An operation of main row activation control circuit 33 shown in FIG. 10A will now be described with reference to a timing chart of FIG. 10B.

When a row active command is externally applied, row active signal ACT generated from the command decoder is rendered active in response to the rising of internal clock signal CLK, and the output signal of NAND circuit 33a attains L-level. Thereby, set/reset flip-flop 33b is set so that main row activating signal RCNTAA rises to H-level. In this operation, the command decoder may activate row active signal ACT at the rising of internal clock signal CLK0. In this case, row active signal ACT shown in FIG. 10B attains H-level in synchronization with the rising of internal clock signal CLK0. In the case where the logic applies, as a command, row active signal ACT in synchronization with external clock signal ECLK, row active signal ACT is already at H-level when internal clock signal CLK0 rises.

When main row activating signal RCNTAA rises to H-level, set/reset flip-flop 33e is set after elapsing of delay time τ1 of delay circuit 33d, and the output signal of inverter 33f attains L-level. Therefore, main row activating signal RCNTAB sent from driver 35cb rises to H-level.

When delay time τ2 of delay circuit 33g then elapses, set/reset flip-flop 33h is reset, and main row activating signal RCNTAC sent from driver 35cc rises to H-level. By utilizing delay circuits 33d and 33g, therefore, these main row activating signals RCNTAA, RCNTAB and RCNTAC can be sequentially and accurately driven to the active state in a predetermined sequence.

When delay time τ3 of delay circuit 33j then elapses, set/reset flipflop 33b is reset, and the output signal of inverter 33c attains H-level so that main row activating signal RCNTAA falls to L-level. When the delay time τ4 of the delay circuit 33l elapses, the output signal of the delay circuit 33l falls, and set/reset flip-flop 33e is reset, and main row activating signal RCNTAB falls to L-level. When delay time τ5 of delay circuit 33n then elapses, set/reset flip-flop 33h is reset, and main row activating signal RCNTAC falls to L-level. Owing to these delay circuits 33j, 33l and 33n, main row activating signals RCNTAA-RCNTAC can be accurately driven to the inactive state in a predetermined sequence.

If these main row activating signals RCNTAA-RCNTAC are generated independently of each other by one-shot pulse generating circuits, the respective one-shot pulse generating circuits may have different operation characteristics due to variations in manufacturing process parameters of transistors. If the delay times in the one-shot pulse generating circuits change, the sequence of activation/deactivation of main row activating signals RCNTAA-RCNTAC may change. If the transistor characteristics change due to variations in process parameters and the pulse width of a one-shot pulse signal is reduced, a circuit at the next stage cannot detect the activation of the main row activating signal, resulting in an operation failure.

However, by utilizing the delay circuits as shown in FIG. 10A, main row activating signals RCNTAA-RCNTAC can be accurately and successively activated in a predetermined sequence, and then can be deactivated in a predetermined sequence even if variations occur in delay times of the delay circuits. Accordingly, even if the characteristics of transistors change due to variations in manufacturing parameters, main row activating signals RCNTAA-RCNTAC can be activated and deactivated stably in accordance with a predetermined fixed sequence without an influence of the variations in operation characteristics.

Modification

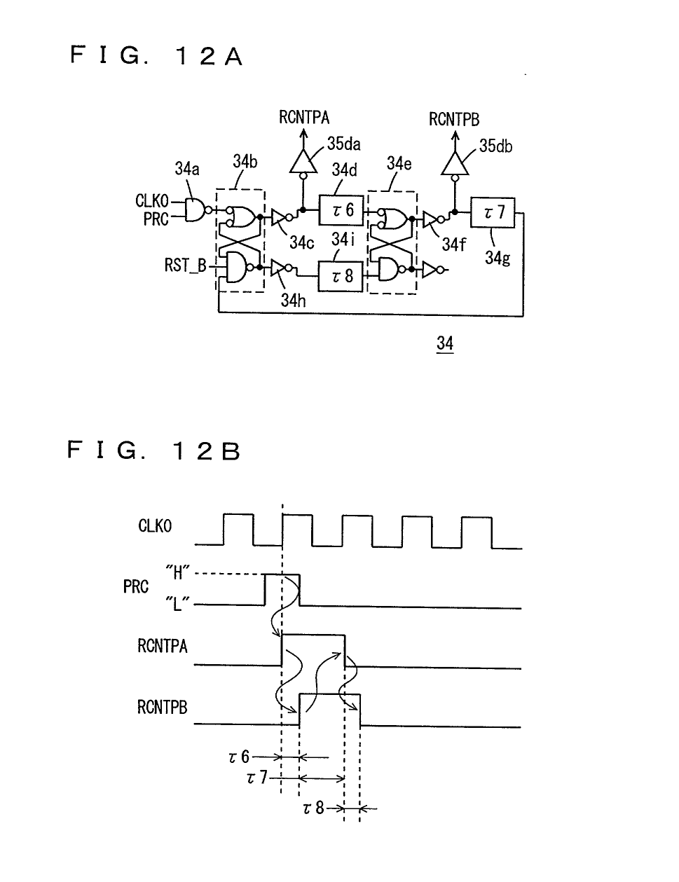

FIG. 11A shows a modification of the main row activation control circuit 33 according to the third embodiment. Main row activation control circuit 33 shown in FIG. 11A differs from the main row activation control circuit 33 shown in FIG. 10A in the following point. More specifically, the main row activating control circuit 33 shown in FIG. 11A includes a delay circuit 33p for delaying the output signal of the inverter 33c by a predetermined time period x0 for application to the subsequent driver 35a and the delay circuit 33d. Other components are the same as those shown in FIG. 10A, and corresponding components are denoted by the same reference numerals.

In the arrangement shown in FIG. 11A, the timing of the main row activating signal RCNTAA can be adjusted by the delay circuit 33p as shown in the operational waveform diagram of FIG. 11B. Referring to FIG. 11A, the main row activating signal RCNTAA is delayed by the delay time τ0 relative to the edge of the internal clock signal CLK0, and the subsequent main row activating signals are sequentially activated in response to the main row activating signal RCNTAA. Thus, the internal timing of the main row activating signals can be adjusted more accurately.

In the arrangement of FIG. 11A, the delay circuit 33p delays the activation and deactivation of main row activating signal RCNTAA, and the pulse width of the main row activating signal RCNTAA can also adjusted by the delay circuit 33p, because the main row activating signal RCNTAA is deactivated after elapse of the delay times τ0 and τ3 when main row activating signal RCNTAC is activated. However, the delay circuit 33p may be configured to delay only one of the activation and deactivation of main row activating signal RCNTAA. For delaying only the activation of main row activating signal RCNTAA, a fall delay circuit for delaying only the fall of the output signal of inverter 33c can be employed.

In the arrangements shown in FIG. 10A and 11A, three phase main row activating signals RCNTAA-RCNTAC are produced in response to row active signals ACT. However, more main row activating signals than three phases may be generated for accurate controlling of the timing of the local row activating signals. For generating the main row activating signals more than three phases, the flip-flops are increased in number, as needed, in the arrangements shown in FIG. 10A and 11A.

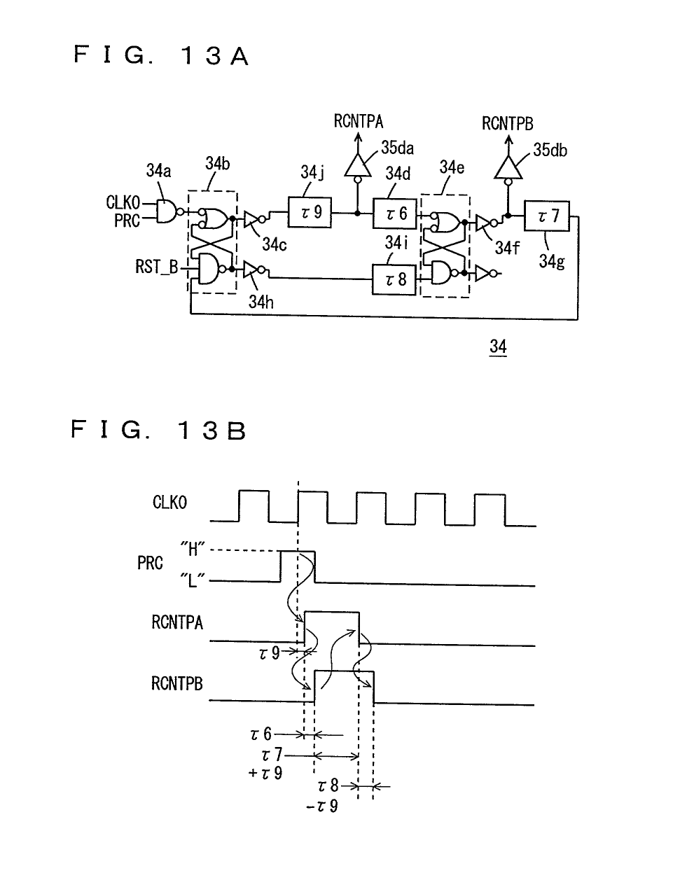

FIG. 12A shows a structure of a main precharge control circuit 34 shown in FIG. 3. In FIG. 12A, main precharge control circuit 34 includes: an NAND circuit 34a which receives internal clock signal CLK0 and precharge instructing signal PRC; a set/reset flip-flop 34b which is set to generate a signal at H-level at its first output when the output signal of NAND circuit 34a is at L-level; an inverter 34c which inverts the signal on the first output of set/reset flip-flop 34b; a driver 35da which inverts an output signal of inverter 34c to produce a main precharge activating signal RCNTPA; a delay circuit 34d which delays the output signal of inverter circuit 34c by a time τ6; a set/reset flip-flop 34e which is set to generate a signal at H-level at its first output when the output signal of delay circuit 34d is at L-level; an inverter 34f which inverts the signal on the first output of set/reset flip-flop 34e; a driver 35db which inverts the output signal of inverter 34f to produce main precharge activating signal RCNTPB; a delay circuit 34g which delays the output signal of inverter 34f by a time τ7; an inverter 34h which inverts a signal on a second output of set/reset flip-flop 34g; and a delay circuit 34i which delays the output signal of inverter 34h by a time of -8 for application to a second input of set/reset flip-flop 34g.

Delay circuit 34g resets set/reset flip-flop 34b when the output signal thereof attains L-level. Set/reset flip-flop 34b also receives a system reset signal RST_B. When system reset signal RST_B is at L-level, set/reset flip-flop 34b is reset. Likewise, when the output signal of delay circuit 34i attains L-level, set/reset flip-flop 34e is reset. The operation of main precharge control circuit 34 shown in FIG. 12A will now be described with reference to a signal waveform diagram of FIG. 12B. Drivers 35da and 35db have the same structure and the same drive capability.

When the precharge instruction is applied, precharge instructing signal PRC attains H-level at the rising edge of internal clock signal CLK0. If the command decoder is not provided, the logic directly applies precharge instructing signal (command) PRC. If the command decoder is employed for decoding the command, precharge instructing signal PRC rises to H-level in response to the rising of internal clock signal CLK0.

When internal clock signal CLK0 rises to H-level, the output signal of NAND circuit 34a attains L-level, and set/reset flip-flop 34b is set so that the output signal of inverter 34c attains L-level. Thus, main precharge activating signal RCNTPA rises to H-level. When delay time τ6 of delay circuit 34d elapses, the output signal of delay circuit 34d attains L-level so that set/reset flip-flop 34e is set, and main precharge activating signal RCNTPB sent from driver 35db rises to H-level.

When main precharge activating signal RCNTPB rises to H-level, the output signal of delay circuit 34e attains L-level after elapsing of delay time τ7 of delay circuit 34g. Thereby, set/reset flip-flop 34b is reset, and main precharge activating signal RCNTPA falls to L-level. When set/reset flip-flop 34b is reset, the output signal of inverter 34h attains L-level, and set/reset flip-flop 34e is reset after elapsing of a delay time τ8 of delay circuit 34i so that main precharge activating signal RCNTPB falls to L-level.

Therefore, these main precharge activating signals RCNTPA and RCNTPB can likewise be activated and deactivated in a predetermined sequence owing to delay circuits 34b, 34g and 34i. Even if variations occur in transistor parameters, the above sequence remains unchanged. Thus, the main precharge activating signals RCNTPA and RCNTPB can be activated and deactivated accurately in a predetermined sequence, so that the precharge control circuit which can operate stable to generate the precharge control signals of two phases can be achieved.

Modification of Main Precharge Control Circuit

FIG. 13A shows a modification of the main precharge control circuit 34. In the arrangement of main precharge control circuit 34, a delay circuit 34j is additionally provided between the output of the inverter 34c, and delay circuit 34d and driver 35da. Delay circuit 34j delays the output signal of inverter 34c by a predetermined time c9 for application to delay circuit 34d and driver 35da. The delay time of delay circuit 34j is adjustable as the other delay circuits 34d, 34g, and 34i. The other construction of the main precharge control circuit 34 is the same as that of the circuit shown in FIG. 12A, and corresponding components are denoted by the same reference numerals.

In the arrangement of FIG. 13A, the activation timing of main precharge activating signal RCNTPA can be adjusted by the delay circuit 34j having the delay time τ9 adjustable as shown in the operation waveform diagram of FIG. 13B. The other main precharge activating signal RCNTPB is activated in response to the activation of main precharge activating signal RCNTPA. Thus, more precise timing adjustment can be achieved. In addition, the deactivation timing of main precharge activating signal RCNTPA is delayed by the delay circuit 34j, and the pulse width of main precharge activation signal RCNTPA can also be adjusted.

In the arrangement of FIG. 13A, the delay circuit 34j delays the activation and deactivation of the main precharge activating signal RCNTPA because main precharge activating signal RCNTPA is deactivated after elapse of the delay times of τ9 and τ7 when main precharge activating signal RCNTPB is activated. However, the delay circuit 34j may be configured to delay only one of the activation and deactivation of main precharge activating signal RCNTPA. A fall delay circuit for delaying the fall of the output signal of inverter 34c can be employed for delaying only the activation of the main precharge activating signal RCNTPA.

As for the main precharge activating signals as well, the number of phases of the main precharge activating signals is not restricted to two, and may be more than two. The number of the flip-flops for generating the main precharge activating signals needs only to be increased depending on the required number of the main precharge activating signals.

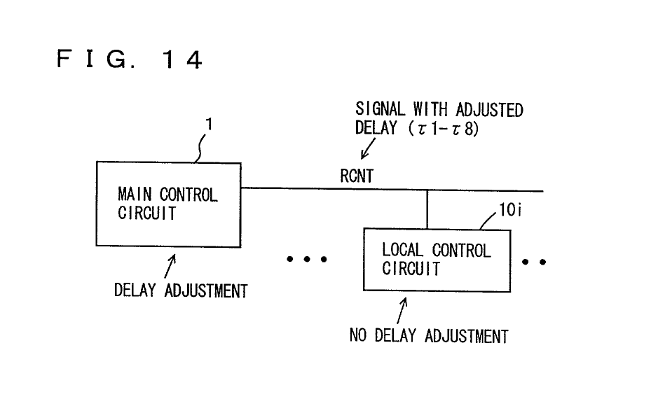

Main row activation control circuit 33 and main precharge control circuit 34 can have the timing of main activating signals adjusted through adjusting of the delay times of delay circuits. More specifically, main control circuit 1 has the delay time of main control signal RCNT (main activating signal and main precharge activating signal) adjusted through the adjustment of the delay time of the delay circuits, to transfer the main control signal subjected to the delay adjustment to local control circuit 10i, as shown in FIG. 14, where the local control circuit 10i representatively indicates local control circuits 10a-10n. Therefore, there is no need to provide delay circuits for adjusting timings of main activating signals RCNTAA-RCNTAC and main precharge activating signals RCNTPA and RCNTPB in each of local control circuits 10a-10n. Accordingly, an area occupied by the local control circuits can be reduced, and steps for timing adjustment can be simplified.

According to the third embodiment of the invention, as described above, activation and deactivation of the main control signals are successively executed by using the delay circuits, and the sequence of activation/deactivation of main control signals can be fixed without an influence by variations in transistor parameters. Therefore, it is possible to produce the control signals of multiple phases, which are activated and deactivated accurately in a predetermined sequence. Mere adjustment of the delay times of the delay circuits in the main control circuit allows the timing adjustment of the main control signals for each local control circuit because the line loads for the respective memory blocks are equal to each other, and the timing relationship is kept. Therefore, an area occupied by the local control circuits can be reduced.

Fourth Embodiment

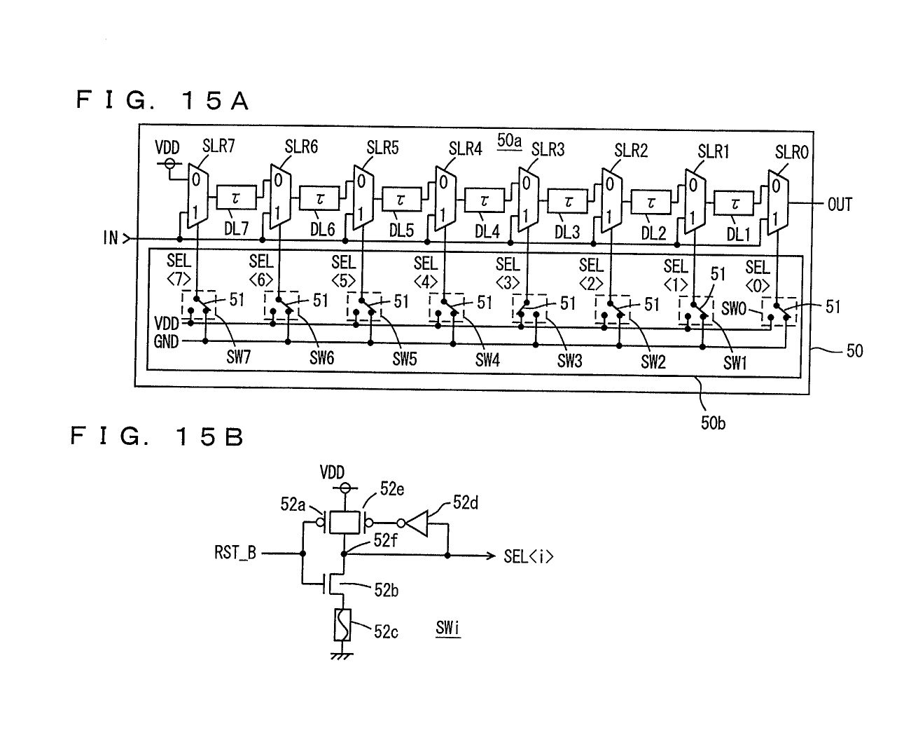

FIG. 15A schematically shows a structure of a delay circuit according to a fourth embodiment of the invention. The delay circuit shown in FIG. 15A is utilized as the delay circuits in main activation control circuit 33 and main precharge control circuit 34 of the main control circuit in the third embodiment described above.

In FIG. 15A, a delay circuit 50 includes a delay portion 50a for delaying input signal IN, and a delay value setting circuit 50b for setting the delay time of delay portion 50a. Delay portion 50a includes: delay stages DL7-DL1 each having a unit delay time τ; select circuits SLR6-SLR0 hare arranged at output portions of delay stages DL7-DL1 for selecting input signal IN or the output signals of corresponding delay stages DL7-DL1 in accordance with corresponding select signals SEL<6>-SEL<0> generated from delay value setting circuit 50b; and a select circuit SLR7 arranged before delay stage DL7 for selecting either input signal IN or a power supply voltage VDD in accordance with a select signal SEL<7> generated from delay value setting circuit 50b. Select circuit SLR0 generates final output signal OUT.

Delay value setting circuit 50b includes switch circuits SW7-SW0, which are provided corresponding to select circuits SLR7-SLR0, for selecting either power supply voltage VDD or ground voltage GND to produce select signals SEL<7>-SEL<0>, respectively.

One of select signals SEL<7>-SEL<0> is set to the level of power supply voltage VDD, and the other signals are set to the level of ground voltage GND. Mask metal interconnection line 51 is used for determining a connection path in the switching circuit SLR. The mask metal interconnection line is formed with a predetermined mask in a manufacturing step to determine the activation and deactivation of the select signals SEL<0>-SEL<7>. In an example shown in FIG. 15A, switch circuit SW3 selects power supply voltage VDD via mask metal interconnection line 51 to produce select signal SEL<3>, and the other select signals SEL<7>-SEL<4> and SEL<2>-SEL<0> are set to ground voltage GND level. In this state, input signal IN is selected by select circuit SLR3, and is applied to delay stage DL3.

Select circuits SLR6-SLR4 and SLR2-SLR0 select the output signals of the preceding delay stages, respectively. Select circuit SLR7 selects power supply voltage VDD. In this state, input signal IN passes through delay stages DL3, DL2 and DL1, and is outputted as output signal OUT via select circuit SLR0. Therefore, output signal OUT has a delay time of 3·τ with respect to input signal IN. The states of select signals SEL<7>-SEL<0> are set by metal mask interconnection lines 51, and the delay time ranging from the maximum value of 7·τ to the minimum value of 0 can be achieved. In this case, delay times of select circuits SLR7-SLR0 are ignored.

In the structure shown in FIG. 15A, delay portion 50a has seven cascaded delay stages. However, the number of delay stages is not restricted to seven stages, and can be appropriately determined in view of variations in wafer process and others.

First Modification

FIG. 15B shows a structure of a first modification of the fourth embodiment of the invention. FIG. 15B shows one switch circuit SWi included in delay value setting circuit 50b. In FIG. 15A, switch circuit SWi includes: a P-channel MOS transistor 52a which is connected between a power supply node and an internal node 52f, and has a gate receiving a reset signal RST_B; an N-channel MOS transistor 52b which is connected at one conduction node to internal node 52f, and has a gate receiving reset signal RST_B; a fusible link element (fuse element) 52c which is connected between another conduction node of MOS transistor 52b and the ground node; an inverter 52d for inverting a signal on node 52f; and a P-channel MOS transistor 52e which is connected between the power supply node and internal node 52f, and has a gate receiving an output signal of inverter 52d. Select signal SEL<i> is generated from internal node 52f.

Reset signal RST_B is rendered L-level for a predetermined time at the time of reset or power-on, and is fixed at H-level during a normal operation otherwise. When fuse element 42c is conductive, the following operation is performed. Even when reset signal RST_B temporarily precharges internal node 52f to power supply voltage VDD, MOS transistor 52b is turned on when reset signal RST_B returns to H-level. Responsively, internal node 52f attains the ground voltage level, and select signal SEL<i> is fixed to L-level. Since inverter 52d generates the signal at H-level (power supply voltage VDD level), MOS transistor 52e maintains the off state.

When fuse element 52c is cut off, internal node 52f is temporarily precharged to power supply voltage VDD level via MOS transistor 52a by reset signal RST_B being L-level. In this case, even when reset signal RST_B returns to H-level to turn off MOS transistor 52a, internal node 52f maintains H-level because the fuse element 52c is cut off. Further, the output signal of inverter 52d is at L-level, and MOS transistor 52e is turned on so that select signal SEL<i> generated at internal node 52f is kept at power supply voltage VDD level.

In the structure of FIG. 15B, the delay value of delay circuit can be set by fuse element 52c. Therefore, the best delay value can be determined in a test at a wafer level after completion of wafer process, and the delay times can be finely adjusted accurately according to variations in process parameters, even if such variations are present.

Second Modification

FIG. 16 shows a structure of a second modification of the fourth embodiment of the invention. In FIG. 16, delay value setting circuit 50b includes fuse circuits 53a-53c for fuse programming, and a decoder 54 for decoding output signals FOUT<2:0> of fuse circuits 53a-53c to produce select signals SEL<7:0>. Fuse circuits 53a-53c have the same structure, and each includes: P-and N-channel MOS transistors 55a and 55b which receive reset signal RST_B on their gates; a fuse element 55c which is connected between MOS transistor 55b and the ground node; an inverter 55d which inverts the output signal of an internal node 55f; and a Pchannel MOS transistor 55e which is turned on to transmit power supply voltage VDD to internal node 55f when the output signal of inverter 55d is at L-level. Output signals FOUT<0>-FOUT<2> are generated from internal nodes 55f. The structures of fuse circuits 53a-53c are the same as that of switch circuit SWi shown in FIG. 15B. Therefore, the logical levels of these output signals FOUT<0>-FOUT<2> can be set (programmed) by blowing or not blowing fuse elements 55c.

Decoder 54 decodes output signals FOUT<2:0> of three bits to produce select signals SEL<7:0> of 8 bits. Therefore, decoder 54 sets one of select signals SEL<7:0> (=SEL<7>-SEL<0>) to H-level, and sets the other select signals at L-level.

By utilizing the delay value setting circuit shown in FIG. 16, it is not necessary to provide a fuse circuit for each of select signals SEL<7:0>, so that the components can be reduced in number, and therefore the occupying area can be reduced.

Third Modification

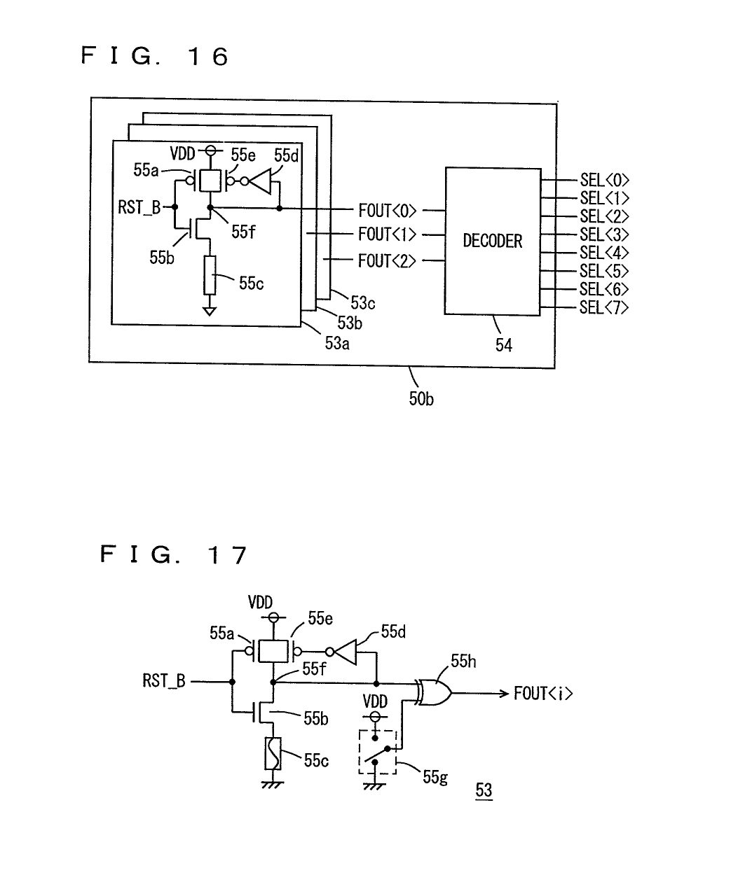

FIG. 17 shows a structure of a third modification of a fourth embodiment of the invention. FIG. 17 shows a modification of the fuse circuit shown in FIG. 16. In FIG. 17, fuse circuit 53 includes, in addition to the structure shown in FIG. 16, a default setting switch 55g for setting initial values, and an XOR circuit 55h receiving a signal on internal node 55f and the output signal of default setting switch 55g to produce an output signal FOUT<i>.

Default setting switch 55g is, e.g., a master slice switch, of which connection path is determined by a metal interconnection line. The master slice switch is formed in a master process of forming only the switch circuit thereof as well as a slice process of forming connection path thereof. In the initial state, fuse element 55c is conductive. Default setting switch 55g is set to the state for selecting power supply voltage VDD or the ground voltage with the assumption that fuse element 55c is conductive. Output signal FOUT<i> generated from XOR circuit 55h attains L-level when default setting switch 55g is set to the state for selecting the ground voltage. When fuse element 55c is blown in the above state, output signal FOUT<i> from XOR circuit 55a attains H-level.

By programming the blowing and non-blowing of fuse element 55c, the logical level of output signal FOUT<i> can be changed, and the delay time set by default setting switch 55g can be adjusted to either a larger value or a smaller value. For example, output signals FOUT<2>, FOUT<1> and FOUT<0>, which were set to L-, L-and H-levels by default setting switch 55g, respectively, are to be readjusted to L-, H-and L-levels by programming fuse elements 55c, respectively. In this case, fuse element 55c for signal FOUT<1> is blown off.

Accordingly, the delay time of delay circuit, which is initially set in the slice process, can be set to an appropriate value in a wafer test after completion of the wafer process, and the shift of the delay value from the designed value can be finely adjusted. In this case, the delay time can also be changed to either a larger value or a smaller value, and the delay time can be accurately and finely adjusted.

According to the fourth embodiment of the present invention, as described above, the timing adjustment of each control signal is performed in the main control circuit, and it is not necessary to arrange the delay stage for timing adjustment of the main control signal in the local control circuit. Therefore, the area of local control circuit can be reduced. Since the number of main control signals is not smaller than the number of actually produced control signals, the required delay circuits can also be small in number, so that the occupation area can be remarkably reduced as compared with the conventional structure.

In the wafer test, the timing and phase of the main control signal can be finely readjusted by programming the fuse elements, and the shift in delay time, which may be caused by variations in parameters in the wafer process, can be finely adjusted. Therefore, the yields of products can be improved.

Fifth Embodiment

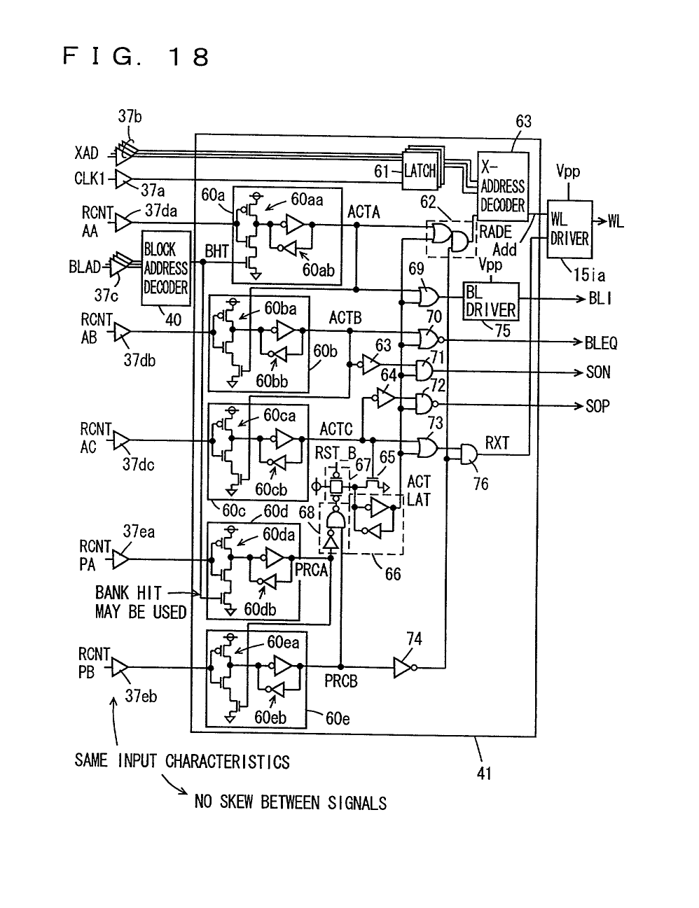

FIG. 18 shows a structure of a row-related local control circuit 41 according to a fifth embodiment of the invention. In FIG. 18, row-related local control circuit 41 includes: a latch circuit 61 which latches a word line address (X address) XAD sent from input circuit 37b in synchronization with the internal clock signal sent from clock input circuit 37a; a buffer circuit 60a which takes in main row activating signal RCNTAA sent from an input circuit 37da, and produces internal row control signal ACTA in accordance with a block hit signal BHT sent from block address decoder 40; an input buffer 60b which produces internal row control signal ACTB in accordance with main row activating signal RCNTAB sent from an input circuit 37db when internal row control signal ACTA is active; an input buffer circuit 60c which produces internal row control signal ACTC in accordance with main row activating signal RCNTAC sent from an input circuit 37dc when internal row control signal ACTB is active; an input buffer circuit 60d which produces an internal precharge control signal PRCA in accordance with block hit signal BHT and main precharge activating signal RCNTPA; and an input buffer circuit 60e which produces an internal precharge control signal PRCB in accordance with main precharge activating signal RCNTPB sent from an input circuit 37eb when internal precharge control signal PRCA is active.

Input circuits 37b correspond to input circuit 37b shown in FIG. 3, input circuits 37da-37dc correspond to input circuit 37d shown in FIG. 3, and input circuits 37ea and 37eb correspond to input circuit 37e shown in FIG. 3. These input circuits 37a, 37b, 37da, 37dc, 37ea and 37eb are the same in structure and in transistor size. Therefore, all the input impedances of these input circuits are equal to each other, and all the loads of signal lines for the respective input signals are equal to each other. Thus, the transmission delays of all the signals for row-related local control circuit 41 are equal to each other.

Input buffer circuit 60a includes: an input circuit 60a a which produces an internal signal in accordance with the output signal of input circuit 34da when block hit signal BHT is at H-level and indicates that the corresponding memory block is selected; and an inverter latch 60ab which latches the output signal of input circuit 60aa. In this input buffer circuit 60a, when block hit signal BIT is at H-level, input circuit 60aa produces an internal row control signal ACTA corresponding to main row activating signal RCNTAA. When block hit signal BHT is at L-level and indicates an unselected state, input circuit 60aa is disabled, and input buffer circuit 60a has its internal signal latched by latch circuit 60ab. Main row activating signal RCNTAA is at L-level during the standby state, and the P-channel MOS transistor in input circuit 60aa is kept on. During standby state, therefore, latch circuit 60ab sets internal row control signal ACTA to L-level. Therefore, internal row control signal ACTA is driven to the active state only for the selected memory block, of which block hit signal BHT is at H-level.

Input buffer circuit 60b includes: an input circuit 60ba which inverts an output signal of an input circuit 30db to produce an internal signal when internal row control signal ACTA is at H-level; and an inverter latch 60b which latches an output signal of input circuit 60ba. Therefore, input circuit 60ba produces the internal signal in accordance with main row activating signal RCNTAB after internal row control signal ACTA is rendered active. Accordingly, an internal row control signal ACTB is driven to the active state after internal row control signal ACTA is driven to the active state.

Input buffer circuit 60c includes: an input circuit 60ca which produces an internal signal in accordance with the signal sent from input circuit 37dc when internal row control signal ACTB is active; and an inverter latch 60cb which latches an output signal of input circuit 60ca. In input buffer circuit 60c, input circuit 60ca produces an internal row control signal ACTC in accordance with main row activating signal RCNTAC after internal row control signal ACTB is rendered active. Therefore, internal row control signal ACTC is driven to the active state after internal row control signal ACTB is rendered active.

Input buffer circuit 60d includes: an input circuit 60da which produces an internal signal in accordance with main precharge activating signal RCNTPA sent from input circuit 37ea when block hit signal BHT is active; and an inverter latch 60db which latches an output signal of input circuit 60da, and produces an internal precharge control signal PRCA. Therefore, internal precharge control signal PRCA is produced in accordance with main precharge activating signal RCNTPA when block hit signal BHT is at H-level. When block hit signal BHT is at L-level, the output signal of input circuit 60da is at H-level so that internal precharge control signal PRCA maintains L-level.

For main precharge activating signal, block hit signal BHT is applied because the precharge operation is performed on a memory block basis. This corresponds to the structure in which one memory block is utilized as a bank. If each bank is formed of a plurality of memory blocks, the precharge operation is executed on a bank basis. In this case, a bank hit signal is applied to input buffer circuit 60d instead of block hit signal BHT.

Input buffer circuit 60e includes: an input circuit 60ea which produces an internal signal in accordance with the output signal of input circuit 37eb when internal precharge control signal PRCA is active; and an inverter latch 60eb which latches the output signal of input circuit 60ea, and produces an internal precharge control signal PRCB. After internal precharge control signal PRCA is rendered active, internal precharge control signal PRCB is driven to the active state. Therefore, internal control signals PRCA and PRCB are sequentially activated in a predetermined sequence.

Input buffer circuits 60a-60e include inverter latches 60ab-60eb, respectively. This is for the purpose of preventing an electrically floating state of the internal control signals even in the case where the output nodes of input circuits 60aa-60ea are in the high impedance state in which both the N-and P-channel MOS transistors are off. The above floating state may occur when main control signal RCNTAB is at H-level and internal control signal ACTA is at L-level.

Row-related local control circuit 41 further includes: an inverter 63 which receives internal row control signal ACTB; an inverter 64 which receives internal row control signal ACTC; an N-channel MOS transistor 65 which receives internal row control signal ACTC on a gate thereof; an inverter latch 66 which latches the voltage on a drain node of MOS transistor 65; a logic circuit 68 which produces a signal for changing the logical level of the latched signal of inverter latch 66 in accordance with internal precharge control signals PRCA and PRCB; a reset circuit 67 which resets the logical level of the latched signal of inverter latch 66 in accordance with the output signal of logic circuit 68 and reset signal RST_B; a composite gate 62 which receives latched signal ACTLAT of inverter latch 66 and internal row control signal ACTA, and produces a row address decode enable signal RADE; an OR circuit 69 which receives internal row control signal ACTA and latched signal ACTLAT; an NOR circuit 70 which receives latched signal ACTLAT and internal row control signal ACTB, and produces a bit line equalize instructing signal BLEQ; an AND circuit 71 which receives the output signal of inverter 63 and latched signal ACTLAT, and produces a sense amplifier activating signal SON; an NAND circuit 72 which receives the output signal of inverter 64 and latched signal ACTLAT, and produces a sense amplifier activating signal SOP; an OR circuit 73 which receives internal row control signal ACTC and latched signal ACTLAT; an inverter 74 which receives internal precharge control signal PLCB; and an AND circuit 75 which receives the output signals of inverter 74 and OR circuit 73, and produces a word line drive timing signal RXT.

Logic circuit 68 produces a reset instructing signal when internal precharge control signals PRCA and PRCB are at L-and H-level, respectively. When reset instructing signal RST_B is at L-level, or the output signal of logic circuit 68 is at L-level, reset circuit 67 sets latched signal ACTLAT of inverter latch 66 to L-level. Therefore, latched signal ACTLAT is driven to the active state of H-level when internal row control signal ACTC attains the active state of H-level, to maintain the active state of H-level until main precharge activating signal RCNTPA is applied subsequently, and internal precharge control signal PRCA attains L-level. Accordingly, when the row active command is applied, the internal row-related control signals maintain the active state in accordance with latched signal ACTLAT even when internal row control signals ACTA-ACTC are each driven in a one-shot pulse form to an active state for a predetermined period.

In the structure shown in FIG. 18, NOR circuit 70 produces bit line equalize instructing signal BLEQ. This structure corresponds to the case where a bit line equalize/precharge circuit is provided in the corresponding memory block, and the bit line precharge/equalize circuit is not shared between adjacent memory blocks. If the bit line precharge/equalize circuit is arranged in a shared sense amplifier band, bit line equalize instructing signal BLEQ is applied to the memory block sharing the sense amplifiers that are used by the corresponding memory block.

Composite gate 62 maintains row address decode enable signal RADE at H-level when one of internal row control signal ACTA and latched signal ACTLAT is at H-level, and the output signal of inverter 74 is at H-level. Therefore, row address decode enable signal RADE generated from composite gate 62 maintains H-level until internal precharge control signal PRCB rises to H-level after application of the precharge command.

Row-related local control circuit 41 further includes: an X-address decoder (word line address decoder) 63 which decodes the word line address latched by latch circuit 61 in response to the activation of row address decode enable signal RADE received from composite gate 62, and produces word line select signal Add; and a BLI driver 75 which drives a bit line isolation instructing signal BLI in accordance with the output signal of OR circuit 69. BLI driver 75 is supplied with a high voltage Vpp as one operation power supply voltage. The logical level of bit line isolation instructing signal BLI depends on the corresponding sense amplifier band structure. In the case where bit line prechargelequalize circuit is provided in each memory block for isolating each bit line of the memory block from the sense amplifier circuit during a standby state, a selected memory block is connected to the sense amplifier circuits. Alternatively, the memory blocks may be connected to the corresponding sense amplifiers in a standby state, and the unselected memory block paired with a selected memory block may be isolated from the sense amplifiers in a row selecting operation. In this case, bit line isolation instructing signal BLI is applied to the bit line isolating circuits of the memory block which shares the sense amplifiers with the corresponding memory block. The scheme of the bit line isolation has only to be appropriately determined in accordance with the structure of the memory array.

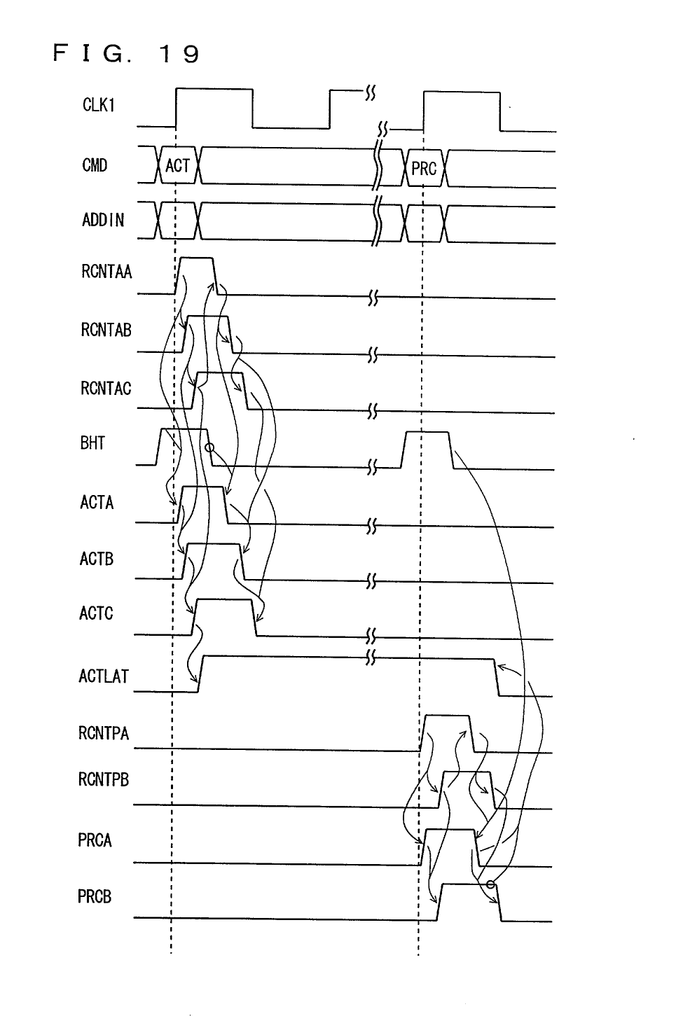

Word line driver (WL driver) 40a is supplied with word line drive timing signal RXT from AND circuit 76. The operation of row-related local control circuit 41 will now be described with reference to a signal waveform diagram of FIG. 19.

Block decoder 40 is supplied with block address signal BLAD from input circuit 37c asynchronously with the clock signal, and block decoder 40 performs the decoding operation by utilizing a setup time of word line address XAD. Therefore, when a row active command is first applied, block hit signal BHT corresponding to the selected memory block rises in accordance with the currently applied address signal.

Then, main row activating signals RCNTAA-RCNTAC are sequentially activated in accordance with row active signal (command) ACT. When block hit signal BHT is at H-level, and main row activating signal RCNTAA attains H-level, input circuit 60aa in input buffer circuit 60a operates, and internal row control signal ACTA rises to H-level. When block hit signal BHT attains L-level and main row control signal RCNTAA attains L-level, the output signal of input circuit 60aa attains L-level, and internal row control signal ACTA attains L-level. When main row control signal RCNTAA is at H-level and block hit signal BHT is at L-level, latch circuit 60ab prevents the internal nodes from being electrically floated.

When internal row control signal ACTA attains H-level, composite gate 62 sets row address decode enable signal RADE to the active state of H-level, and word line address XAD latched by latch 61 in synchronization with internal clock signal CLK1 is decoded, and word line select signal Add is activated.

When internal row control signal ACTA rises to H-level, input buffer 60b is enabled to raise internal row control signal ACTB to H-level in accordance with main row activating signal RCNTAB. When internal row control signal ACTB attains H-level, bit line equalize instructing signal BLEQ attains L-level, and the precharge/equalize operation of the bit line of corresponding memory block is completed. When internal row control signal ACTA attains H-level, BLI driver 75 drives bit line isolation instructing signal BLI to H-or L-level depending on the array structure, to couple the corresponding memory block to the corresponding sense amplifier band because the output signal of OR circuit 69 attains H-level.

When internal row control signal ACTB is driven to H-level, input buffer circuit 60c drives internal row control signal ACTC to H-level in accordance with main row activating signal RCNTAC. When internal row control signal ACT is driven to H-level, MOS transistor 65 is turned on, and latched signal ACTLAT of latch circuit 66 is driven to H-level. During operation of the row-related circuitry, the output signal of inverter 74 is at H-level. Therefore, when internal row control signal ACTC attains H-level and the output signal of OR circuit 73 attains H-level, word line drive timing signal RXT is driven to H-level, and WL driver (word line driver) 40a drives a word line WL to the selected state in accordance with word line select signal Add received from X-address decoder 63.

When internal row control signal ACTB attains L-level while latched signal ACTLAT is at H-level, sense amplifier activating signal SON generated from AND circuit 71 is driven to the active state of H-level, and the N-sense amplifier in the sense amplifier circuit operates. When internal row control signal ACTC subsequently falls to L-level, the output signal of inverter circuit 64 attains H-level, and sense amplifier activating signal SOP generated from NAND circuit 72 attains L-level so that the P-sense amplifier in the sense amplifier circuit operates to pull up the bit line. This state is maintained while latched signal ACTLAT is at H-level.

When the precharge command is applied and the precharge activating signal PRCA rises to H-level, block hit signal BHT attains H-level so that input buffer circuit 60d operates to drive internal precharge control signal PRCA to H-level in accordance with main precharge control signal RCNTPA. Logic circuit 68 maintains its output signal at H-level, and latched signal ACTLAT maintains H-level.

When internal precharge control signal PRCA attains H-level, input buffer circuit 60e drives internal precharge control signal PRCB to H-level in accordance with main precharge activating signal RCNTPB. When internal precharge control signal PRCB attains H-level, the output signal of inverter circuit 74 attains L-level, and word line drive timing signal RXT generated from AND circuit 76 attains L-level. Further, row address decode enable signal RADE generated from composite gate 62 attains the inactive state of L-level, and the selected word line is driven to the unselected state. When internal precharge control signal PRCA subsequently falls to L-level, the output signal of logic circuit 68 attains L-level so that latched signal ACTLAT attains L-level, and each row-related control signal is inactivated and driven to the reset state (standby state).

Internal precharge control signal PRCA is driven to L-level when block hit signal BHT attains L-level and main precharge control signal RCNTPA attains L-level. Responsively, internal precharge control signal PRCB is driven to L-level when internal precharge control signal PRCA attains L-level and main precharge control signal RCNTPB attains L-level. Therefore, these internal precharge control signals PRCA and PRCB likewise have pulse-like waveforms, respectively.

Input buffer circuits 60a-60e are enabled in accordance with the internal control signals from the preceding stages, respectively. Thereby, the internal control signals can be sequentially and accurately driven to the active state in the predetermined sequence. Therefore, even if variations occur in operation parameters, these internal control signals can be successively and accurately driven to the active state in a predetermined sequence, and the internal row-related control signals can be activated and deactivated in a predetermined sequence.

Input buffer circuits 60a-60c are activated in the same sequence as that of main row activating signals to activate internal row-related signals. Input buffer circuits 60d and 60e are successively activated in the precharge operation, to produce the internal row control signals in accordance with main row precharge control signals RCNTPA and RCNTAB, respectively. Therefore, each bank is activated and deactivated in an interleaved manner, and the internal row control signals can be accurately produced in each local control circuit even when a next row active signal is applied while the control signals described above are active.

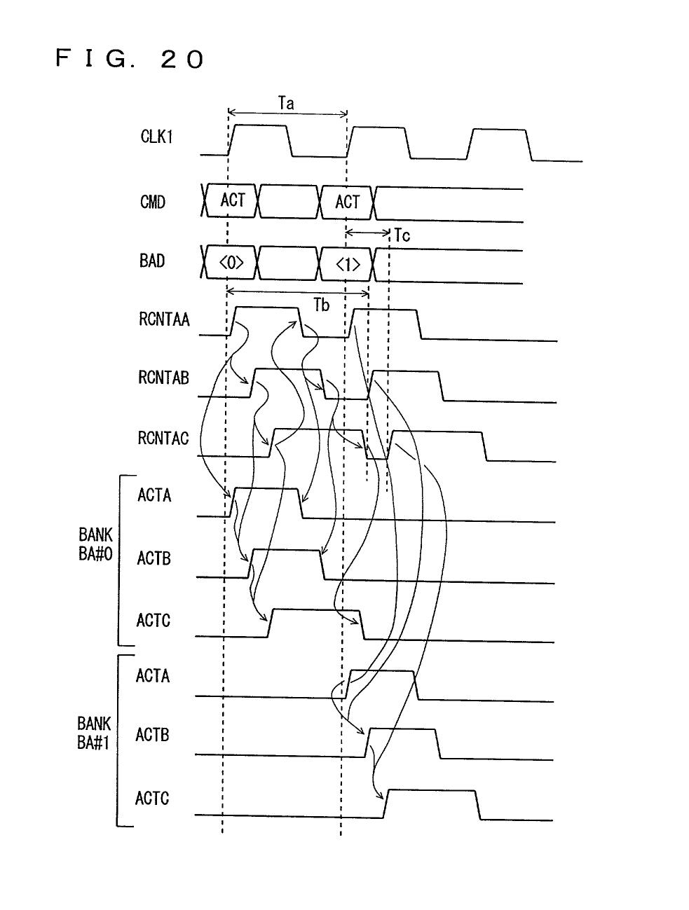

FIG. 20 is a signal waveform diagram representing a fast operation of the row-related local control circuit according to the fifth embodiment of the invention. In FIG. 20, the row active command is applied in synchronization with internal clock signal CLK1, and a bank address BAD<0> specifying bank BA#0 is applied. In accordance with row active command (row active signal ACT), main row activating signals RCNTAA-RCNTAC are successively activated. Responsively, internal row control signals ACTA-ACTC are driven to the selected state in bank BA#0, and an addressed row in bank BA#0 is driven to the selected state.

Internal clock signal CLK1 (external clock signal ECLK) is a fast clock signal. When the row active command (row active signal ACT) for bank BA#1 is applied in the next clock cycle, the main control circuit drives main row activating signals RCNTAA-RCNTAC to the selected state again. In this case, even when main row activating signal RCNTAC is active, main row activating signal RCNTAA can be driven to the active state in the main control circuit again if main row control signal RCNTAA is already driven to the inactive state. Therefore, main row activating signals RCNTAA-RCNTAC are driven to the active state again. In bank BA#1, therefore, internal row control signals ACTA-ACTC are driven to the active state in accordance with main row control signals RCNTAA-RCNTAC.

Therefore, the row-related local control circuit can accurately produce the internal row-related control signals for each bank, provided that the time parameters Ta, Tb, and Tc satisfy the following relationship, where the time Tb represents a time period required after main row control signal RCNTAA is driven to the active state and before main row control signal RCNTAC is driven to the inactive state, the time Ta indicates a cycle of clock signal CLK (CLK1), and the time Tc represents a time difference between main row control signals RCNTAA and RCNTAC:

Tb<Ta+Tc.

As can be seen from the structure of the row-related local control circuit, the memory block can be used as a bank. By utilizing the bank hit signal instead of block hit signal BHT, each row-related local control circuit can be operated as the row-related control circuit for the bank.

According to the fifth embodiment of the invention, as described above, the row-related local control circuits each operate to enable successively the input buffer circuits in accordance with the main row control signals, for producing the internal row control signals, and the internal row-related control signals based on the internal row control signals. Therefore, the row-related control signals can be produced accurately by producing the internal row control signals in a predetermined sequence. Even in the fast operation, therefore, the semiconductor memory device can accurately takes in the main row control signals for producing the row-related control signals in a predetermined sequence, and therefore can perform fast and stable operation.

Sixth Embodiment

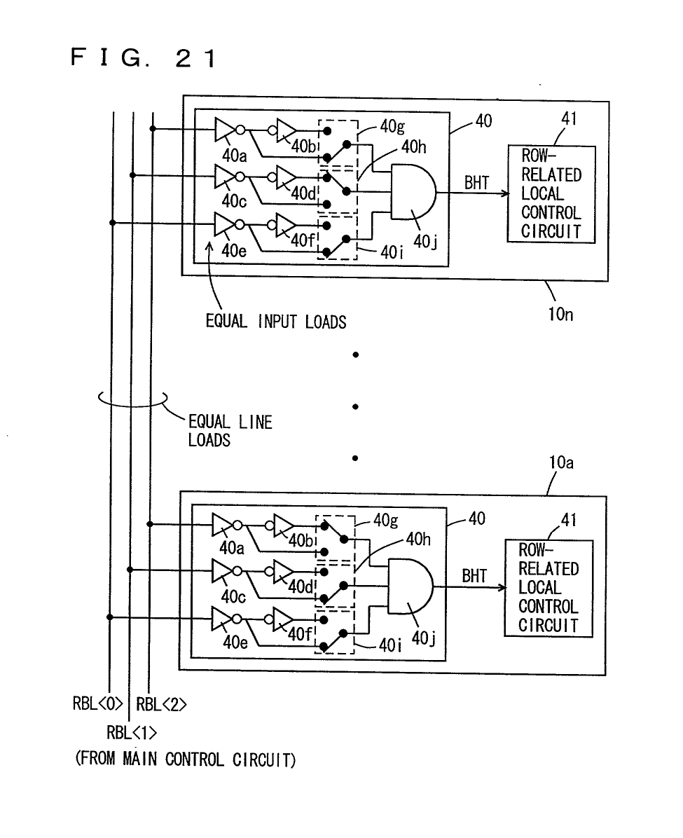

FIG. 21 shows a structure of a block address decoder 40 according to a sixth embodiment of the invention. In FIG. 21, block decoders 40 of the same structure are arranged in local control circuits 10a-10n, respectively. Block hit signals BHT sent from block address decoders 40 are applied to local row-related control circuits 41, respectively.

In FIG. 21, block address decoder 40 includes: inverter circuits 40a, 40c and 40e which receive block address bits RBL<2>-RBL<0> from the main control circuit, respectively; inverter circuits 40b, 40d and 40f which invert the output signals of inverter circuits 40a, 40c and 40e, respectively; a switch circuit 40g which selects one of the output signals of inverter circuits 40a and 40b; a switch circuit 40h which selects one of the output signals of inverter circuits 40c and 40d; a switch circuit 40i which selects one of the output signals of inverter circuits 40e and 40f; and an AND circuit 40j which receives the output signals of switch circuits 40g, 40h and 40i, and produces block hit signal BHT.

Each of switch circuits 40g-40i are formed of metal interconnection lines. Inverter circuits 40a-40f produce complementary bits of block address bits RBL<2>-RBL<0>. Each of switch circuits 40g-40i selects one of the paired bits complementary to each other, and the block address can be programmed. When corresponding memory block is designated, block hit signal BHT sent from AND circuit 40a is driven to H-level.

These inverter circuits 40a, 40c and 40e in the input stages may be formed of the transistors of the same size for providing the same input impedance. More specifically, all block address decoders 40 in local control circuits 10a-10n can have the same input impedance. Thus, all the signal line loads of block address bits RBL<2>-RBL<0> can be equal to each other, to eliminate a signal skew between the memory blocks. Thus, the signals can be applied to block address decoders 40 of local control circuits 10a-10n with the same timing relationship.

Block address bits RBL<2>-RBL<0> are block address bits included in the externally applied address signal, and are undecoded signal bits. By producing the complementary address bits in each block address decoder 40, the interconnection lines for transmitting the block address signal from the main control circuit to local control circuits 10a-10n can be reduced in number, and the area occupied by the interconnections can be reduced. Utilizing the setup times of the word line addresses in row-related local control circuits 10a-10n, the block address can be decoded.

Block address decoder 40 decodes the row block address of 3 bits in the case where eight memory blocks are arranged in one bank. Bank expansion can be easily achieved for adding a bank including eight memory blocks because the block address decoder of the same structure can be used without modification. Furthermore, each of switch circuits 40g-40i selects one of the complementary address bits in a pair by utilizing the mask metal interconnection. Thus, only provision of the mask interconnection line is required, and provision of transistors is not required so that an area occupied by the switch circuits can be reduced.

In the layout process, the same structures can be employed for all the block address decoders of the local control circuits, and it is merely required to change the connection paths of the switch circuits in accordance with the block addresses of the memory blocks. Therefore, the design efficiency can be improved.

With the signal interconnection lines of the same length employed for block address bits RBL<2>-RBL<0>, these signal interconnection lines can reliably have the same line load.

An inverter circuit having the same structure as inverter circuits 40a, 40c and 40b in the input stage of block address decoder 40 can be utilized as a receiving circuit for receiving the main row-related control signal sent from main control circuit. Thus, accurate operations can be ensured while preventing a skew between the main row-related control signals as well as a difference in skews, which in turn might occur between the row address signal bits and the main row-related control signals, between memory blocks.

Inverters 40a, 40c and 40e in the input stage correspond to input circuit 37c shown in FIG. 18.

First Modification

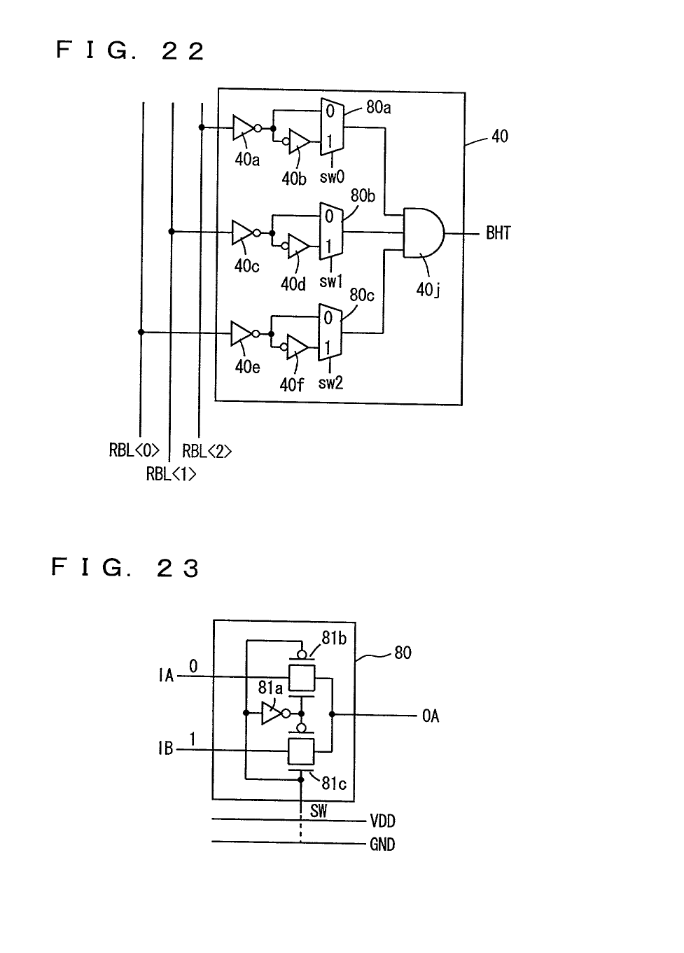

FIG. 22 schematically shows a structure of a first modification of the sixth embodiment of the invention. In the structure shown in FIG. 22, block address decoder 40 includes select circuits 80a-80c instead of switch circuits 40h-40i. Select circuits 80a-80c have the select paths set by switch signals SW0-SW2, respectively. The other structures of block address decoder 40 shown in FIG. 22 are the same as those shown in FIG. 21. The corresponding portions bear the same reference numerals, and description thereof is not repeated.

FIG. 23 shows an example of the structures of select circuits 80a-80c shown in FIG. 22. In FIG. 23, only one select circuit 80 is shown because select circuits 80a-80c have the same structure. Select circuit 80 includes: an inverter 81a which inverts a switch signal SW; a transmission gate 81b which selects an input signal IA in response to switch signal SW and the output signal of inverter 81a; and a transmission gate 81c which is rendered conductive complimentarily with transmission gate 81b in response to switch signal SW and the output signal of inverter 81a, to select an input signal IB. One of these transmission gates 81b and 81c is made conductive in accordance with switch signal SW, and one of input signals IA and IB is selected to produce an output signal OA.

Switch signal SW is produced by coupling a mask metal interconnection to a power supply that supplies power supply voltage VDD or to ground voltage GND.

According to the block address decoder shown in FIG. 22, it is merely required to change the voltage levels of switch signals SW0-SW2, and it is possible to employ the block address decoders of the same layout in all the memory blocks. Therefore, the local control circuits of the same structure can be employed for the respective memory blocks. Accordingly, it is not necessary to provide the block address decoders having different arrangements (layouts) for the respective memory blocks so that the structures of the whole circuits can be made simple, and can be easily adapted to the change in number of the memory blocks.

Second Modification

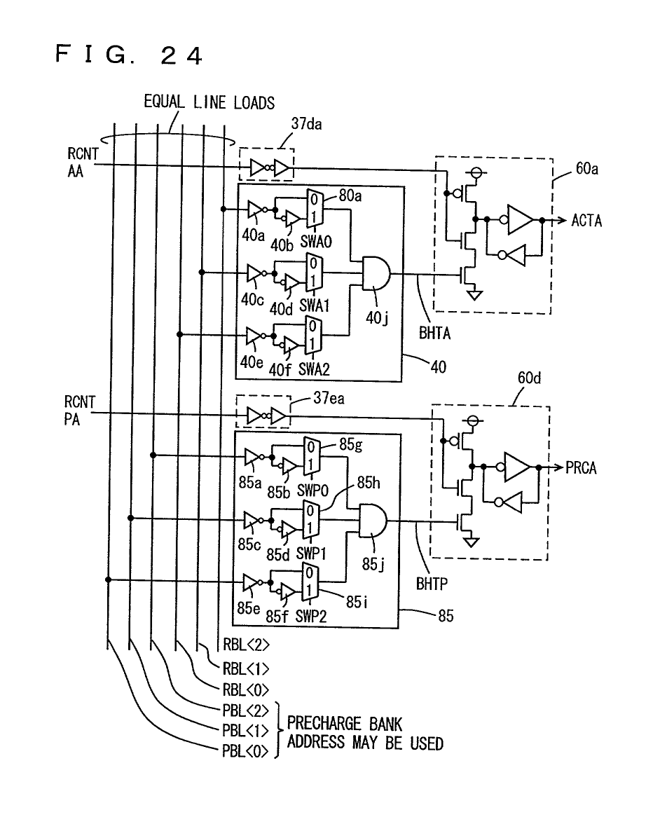

FIG. 24 shows a structure of a modification of a block address decoder according to a sixth embodiment of the invention. In the structure shown in FIG. 24, block address decoder 40, which decodes the block address when the row active command is applied, is provided independently of a precharging block address decoder 85, which decodes a precharge block address applied in the precharging operation together with a precharge command. Block address decoder 40 for the row activation has the same structure as that shown in FIG. 22, and the corresponding portions bear the same reference numerals. However, select circuits 80a-80c are supplied with switch signals SWAO-SWA2 instead of the switch signals sw0 to sw2, respectively. Block hit signal BHTA generated from block address decoder 40 is applied to input buffer circuit 60a in the next stage. Input buffer 60a in the next stage is supplied with main row activating signal RCNTAA via driver 37da. When block hit signal BHTA is in the selected state of H-level, input buffer circuit 60a drives the internal row control signal ACTA to the active state.

Block address decoder 85 for precharging includes: inverter circuits 85a and 85b which produce complementary address bits from precharge block address bit PBL<2>; inverter circuits 85c and 85d which are connected in series, and produce complementary address bits from precharge block address bit PBL<1>; inverter circuits 85e and 85f which are connected in series, and produce complementary address bits from precharge block address bit PBL<0>; a select circuit 85g which selects one of the output signals of inverter circuits 85a and 85b in accordance with a switch signal SWP0; a select circuit 85h which selects one of the output signals of inverter circuits 85c and 85d in accordance with a switch signal SWP1; a select circuit 85i which selects one of the output signals of inverter circuits 85e and 85f in accordance with a switch signal SWP2; and an AND circuit 85j which produces a precharge block hit signal BHTP in accordance with the output signals of select circuits 85g-85i.

Precharge block address bits PBL<2>-PBL<0> define the precharge operation on a block basis. Thus, the memory block can be used as one bank. If the bank includes a plurality of memory blocks, the bank address bits for precharging are applied instead of precharge block address bits PBL<2>-PBL<0>. If the banks are two in number, one bit (e.g., PBL<2>) among the precharge block address bits is changed in accordance with the bank address for precharging, and the other precharge block address bits PBL<1> and PBL<0> are fixed, e.g., to H-level. Thereby, the plurality of memory blocks included in a selected bank can be simultaneously precharged.

In the structure shown in FIG. 24, block address decoder 40 for row activation and block address decoder 85 for precharging have the same structure, and all inverter circuits 40a-40c, 40e, 85a, 85c and 85e at the input stage have the same input load (input impedance). Thus, the line loads for address bits PBL<2:0> are equal to each other, and the transmission delays of these signals are all equal to each other for each memory block. Therefore, even if the memory blocks or the banks increase in number, the skew of the block address bits in each memory block does not change independently of the number of memory blocks, and the decoding operation and the internal operation can be accurately performed.

The block address bits are merely applied to the local control circuits after buffering by the main control circuit, and the block address bits are decoded within the local control circuits. Thus, the signal lines for transferring the address bits from the main control circuit to the local control circuits can be reduced in number, and the interconnection layout area therefor can be reduced.

Third Modification

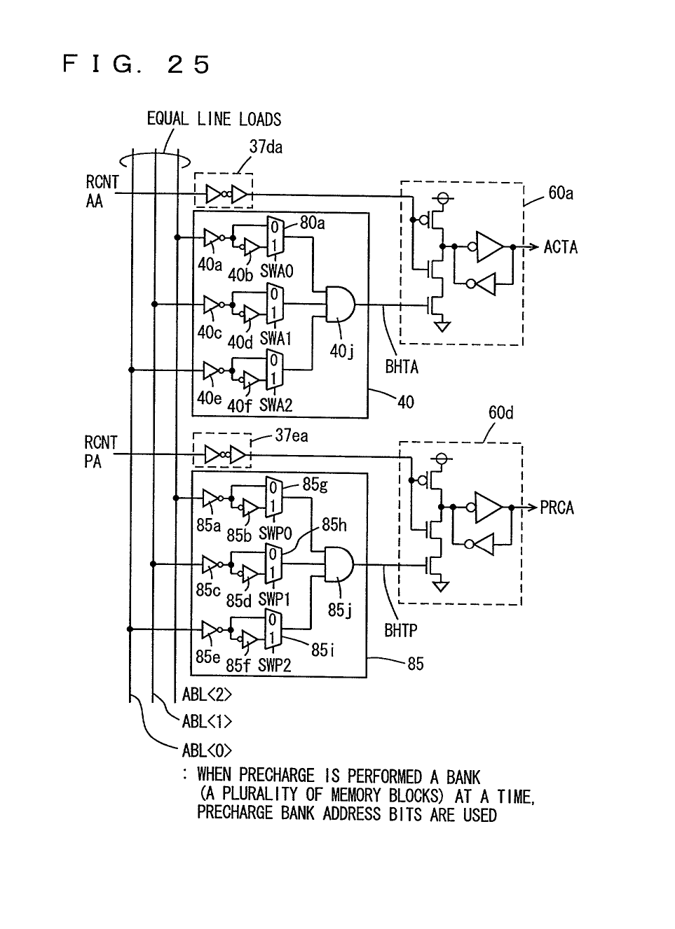

FIG. 25 shows a structure of a third modification of the sixth embodiment of the invention. In the structure shown in FIG. 25, the block address bits for precharging and the block address bits for row activation are transmitted via the same signal lines. Thus, block address decoders 40 and 85 are commonly supplied with address bits ABL<2>-ABL<0> from the main control circuit. The bank/block address bits for precharging are applied via the same input nodes as the block address bits for row activation in each local control circuit. This can also reduce the number of signal lines.

The structures other than the above shown in FIG. 25 are the same as those shown in FIG. 24. The corresponding portions bear the same reference numerals, and description thereof is not repeated.

In the structure shown in FIG. 25, block address decoders 40 and 85 drive the block hit signals BHTA and BHTP to the active state based on block address bits ABL<2>-ABL<0>. However, only one of main row activating signals RCNTAA and RCNTPA is activated depending on whether the applied command is the row active command or the precharge command, and both main row activating signals RCNTAA and RCNTPA are never activated simultaneously. Therefore, only one of internal row control signals ACTA and PRCA is driven to the active state in accordance with the applied command, and the accurate internal operation is ensured.

According to the sixth embodiment, as described above, the block address decoder arranged in the local control circuit decodes the address signal bits, and the block address decoders in the respective memory blocks have the same structure. Thus, the loads of the block address bits are made equal to each other, and the skew between signals in each memory block is not different from those in other memory blocks. Therefore, accurate internal operations can be ensured. Increase in number of the memory blocks or the banks can be accommodated merely by additionally providing the local control circuit of the same circuit structure, and therefore the change in number of the memory blocks or banks can be easily accommodated. Even if the banks or memory blocks increase in number, the load of each address bit does not change, and the skew between signals in each memory block does not vary from the skews in other memory blocks so that accurate operations can be ensured.

Seventh Embodiment

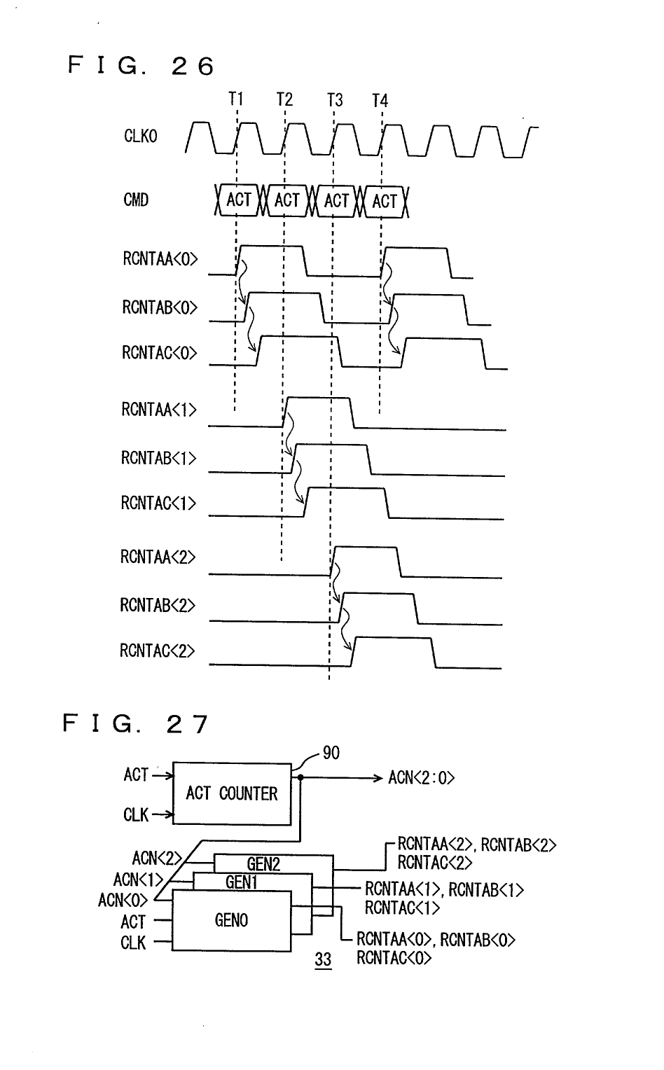

FIG. 26 shows a sequence of generation of main row activating signals of the main control circuit according to a seventh embodiment of the invention. In FIG. 26, an external logic directly applies row active command ACT. Thus, in this embodiment, a command decoder for decoding a command is not provided. The main control circuit includes a plurality of sets of circuits for producing main row activating signals RCNTAA-RCNTAC. By sequentially activating the main row activating signals, the main row activating signal generating circuits are sequentially activated in accordance with externally applied row active command ACT, to drive main row activating signals RCNTAA-RCNTAC to the active state.

At a time T1 in FIG. 26, row active command ACT is applied. Responsively, one set of the main row activating signal generating circuits is first activated, and main row activating signals RCNTAA<0>-RCNTAC<0> are sequentially activated.

While main row activating signal RCNTAA<0> is active, row active command ACT for another bank is applied again at time T2. Another main row activating signal generating circuitry is activated, and main row activating signals RCNTAA<1>-RCNTAC<1> are sequentially activated in accordance with row active command ACT applied at time T2.

At a time T3, row active command ACT designating a further bank is applied. Thereby, further main row activating signal generating circuitry is activated, and main row activating signals RCNTAA<2>-RCNTAC<2> are sequentially activated in accordance with row active command ACT applied at time T3.

When row active command ACT is applied again at a time T4, the main row activating signal generating circuit, which is first activated, is already returned to the standby state, and is activated responsively, to sequentially activate main row activating signals RCNTAA<0>-RCNTAC<0> in accordance with row active command ACT applied at time T4.

Therefore, the main row activating signals can be internally produced, and the row selection can be performed even if the row active commands are applied in the bank interleaved manner in accordance with fast clock signal CLK(CLK0). These main row activating signals RCNTAA-RCNTAC are independent of the bank address, and are activated when row active command ACT is applied. Therefore, even if the number of banks changes, it is not necessary to change the structure of the main row activating signal generating circuitry at all, and the change in bank structure can likewise be accommodated easily.

FIG. 27 schematically shows a structure of a main row activation control circuit 33. In FIG. 27, main row activation control circuit 33 includes an ACT counter 90 which counts active command ACT in response to the rising of clock signal CLK(CLK0), and main row activating signal generating circuits GEN2-GEN0 which are enabled in response to a count value ACN<2:0>, to produce main row-related control signals RCNTAA<2>-RCNTAC<2> and RCNTAA<1>-RCNTAC<1> and RCNTAA<0>-RCNTAC<0> in accordance with clock signal CLK and active command ACT.

ACT counter 90 updates its count bits ACN<2:0> when row active command ACT is applied at the rising of clock signal CLK (CLK0). Main row activating signal generating circuits GEN2-GEN0 are enabled in accordance with count bits ACT<2>-ACN<0>, respectively, to activate the corresponding main row activating signals in a predetermined sequence according to clock signal CLK and row active command ACT. These main row activating signal generating circuits GEN0-GEN2 are equivalently corresponding to the structure shown in FIG. 10, but is configured to receive the corresponding count bit by the NAND gate at the input stage. These main row activating signal generating circuits GEN0-GEN2 are sequentially activated in accordance with count bits ACT<2:0>, whereby the main row control signals can be accurately produced even in the fast operation as shown in FIG. 26.

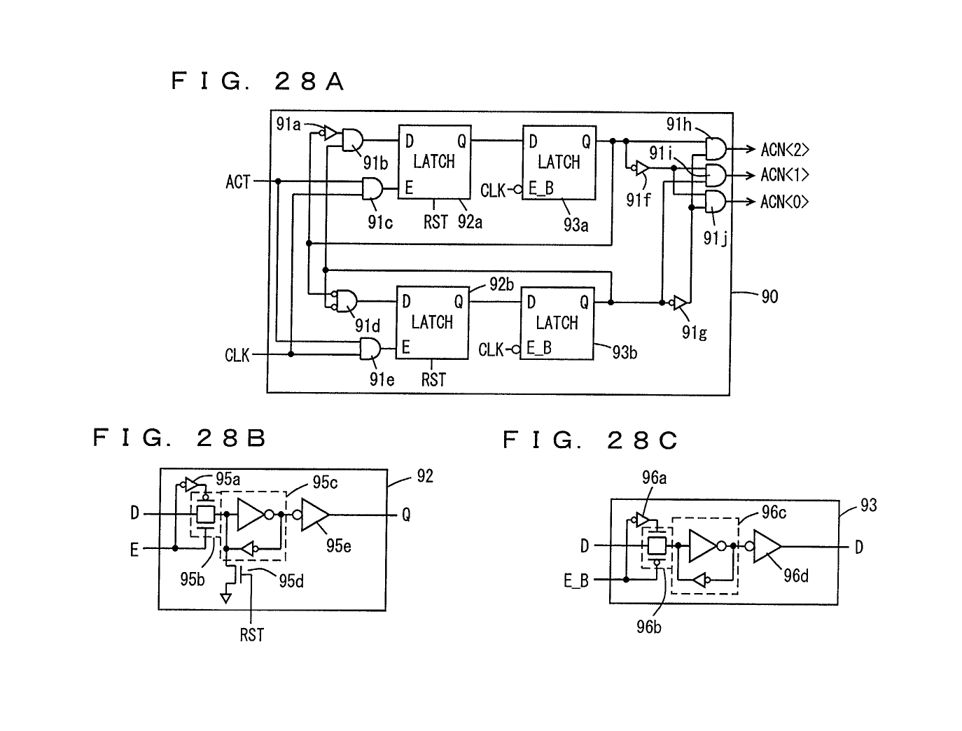

FIG. 28A schematically shows a structure of the ACT counter shown in FIG. 27. In FIG. 28A, ACT counter 90 includes: AND circuits 91c and 91e each of which receive row active command (signal) ACT and clock signal CLK (CLK0); a latch 92a which latches the signal applied to input D thereof in response to the output signal of AND circuit 91c; a latch 92b which latches the signal applied to input D thereof in response to the output signal of AND circuit 91e; latches 93a and 93b which latch the signals generated from outputs Q of latches 92a and 92b in response to clock signal CLK, respectively; an inverter 91a which receives the signal from outputs Q; an AND circuit 91b which receives the signal generated from output Q of latch 93b and the output signal of inverter 91a and applies an output signal thereof to input D of latch 92a; and an NOR circuit 91d which receives the signals from outputs Q of latches 93a and 93b and applies an output signal thereof to input D of latch 92b.

Each of latches 92a and 92b takes in the signal applied to the input D when the signal applied to its input E is at H-level, and attains the latch state when the signal applied to its input E attains L-level. In each of latches 92a and 92b, the signal on its output Q is reset to L-level in response to reset signal RST.

Each of latches 93a and 93b takes in the signal applied to its input D thereof when clock signal CLK is at L-level, and enters the latch state when clock signal CLK is at H-level.

ACT counter 90 further includes: an inverter 91f which receives the signal from output Q of latch 93a; an inverter 91g which receives the signal from output Q of latch 93b; an AND circuit 91h which receives the signal generated from output Q of latch 93a (referred to as the “output signal”, hereinafter) and the output signal of inverter 91g, and produces count bit ACN<2>; an AND circuit 91i which receives the output signals of inverter 91f and latch 93b, and produces count bit ACN<1>; and an AND circuit 91j which receives the output signals of inverters 91f and 91g, and produces count bit ACN<0>.

This ACT counter 90 is a counter of 2 bits. Latches 92b and 93b calculate the count value of the lower bit, and latches 92a and 93a calculate the count value of the higher bit. Inverters 91f and 91g as well as AND circuits 91h-91j form a decode circuit for decoding these count bits.

FIG. 28B shows a structure of latches 92a and 92b shown in FIG. 28A. Since latches 92a and 92b have the same structure, FIG. 28B shows only one latch 92 as a representative.

In FIG. 28B, latch 92 includes: an inverter 95a which receives a signal applied to an input E; a transmission gate 95b which passes a signal applied to an input D in accordance with the signal received from inverter 95a and the signal on input E; an inverter latch 95c which latches the signal transferred from transmission gate 95b; an inverter 95e which inverts the latched signal of inverter latch 95c, and outputs the inverted signal from output Q; and a resetting transistor 95d which resets the latched signal of inverter latch 95c in accordance with reset signal RST.

In FIG. 28B, resetting transistor 95d is formed of an N-channel MOS transistor. When reset signal RST attains H-level, resetting transistor 95d holds the input node of inverter latch 95c at the ground potential level, to set the signal on output Q to L-level.

FIG. 28C shows a structure of latches 93a and 93b shown in FIG. 28A. Since latches 93a and 93b have the same structure, FIG. 28C shows only one latch 93 as a representative.

In FIG. 28C, latch 93 includes: an inverter 96a which inverts the signal applied to an input E_B; a transmission gate 96b which passes the signal applied to an input D in accordance with the signal on input E_B and the output signal of inverter 96a; an inverter latch 96c which latches the signal transmitted from transmission gate 96b; and an inverter 96d which inverts the latched signal of inverter latch 96c, and applies the inverted signal to output Q.

Latch 93 shown in FIG. 28C is not provided with a reset function. Latches 92a and 92b in the preceding stage has a reset function, and the latched signals of these latches 93a and 93b are reset to the initial state in synchronization with clock signal CLK applied to input E_B. Now, an operation of the ACT counter shown in FIGS. 28A-28C will be briefly described below.

In the initial state, latches 92a and 92b are reset by reset signal RST, and the signals on their outputs Q are at L-level. When clock signal CLK attains L-level, latches 93a and 93b take in and latch the output signals of latches 92a and 92b, respectively, so that latches 93a and 93b output the output signals at L-level. In the initial state, therefore, the output signals of inverters 91f and 91g are at H-level, so that count bit ACN<0> from AND circuit 91j is at H-level, and the remaining count bits ACT<2:1> are both at L-level.

While row active command ACT is not supplied, AND circuits 91c and 91e output the signals at L-level, and transmission gate 95b shown in FIG. 28B is non-conductive, so that latches 92a and 92b maintain the latch state. Therefore, ACT counter 90 maintains the reset state until the active command is applied. In this state, the output signal of NOR circuit 91d is at H-level, and the output signal of AND circuit 91b is at L-level.

When row active command ACT is applied, the output signals of AND circuits 91c and 91e attain H-level in synchronization with the rising of clock signal CLK, and latch 92a takes in the output signal of AND circuit 91b, and generates the signal at L-level at its output Q. Meanwhile, latch 92b takes in the signal at H-level from NOR circuit 91d in response to the rising of output signal of AND circuit 91e, and generates the signal at H-level. While the clock signal CLK is at H-level, latches 93a and 93b are in the latch state. Therefore, when row active command ACT is applied in the above state, main row activating signal generating circuit GEN0 shown in FIG. 27 is in the enabled state, and produces main row activating signals RCNTAA<0>-RCNTAC<0> in accordance with row active command ACT.

When clock signal CLK attains L-level, transmission gate 96b shown in FIG. 28C is turned on to take in and generate the output signals of latches 92a and 92b at its output Q. Accordingly, the output signal of latch 93b attains H-level, and the output signal of latch 93a maintains L-level. In response to the change in output signals of latches 93a and 93b, the output signal of inverter circuit 91a falls to L-level. The output signal of inverter circuit 91f is at H-level. Therefore, count bit ACN<1> generated from AND circuit 91i rises to H-level, and count bit ACN<0> falls to L-level. When the output signal of latch 93b rises to H-level, the output signal of NOR circuit 91d attains L-level, and the output signal of AND circuit 91b attains H-level.

When row active command ACT is applied again, latch 92b takes in and outputs the signal at L-level generated from NOR circuit 91d, and latch 92a takes in and outputs the signal at H-level received from AND circuit 91b. Therefore, when clock signal CLK subsequently falls to L-level, latch 93a generated the signal at H-level, and latch 93b generates the signal at L-level. Therefore, the output signal of inverter 91d attains H-level, and the output signal of inverter 91f attains L-level. Also, count bit ACN<1> from AND circuit 91i becomes L-level, and count bit ACN<2> from AND circuit 91h attains H-level.

When the output signal of latch 93a attains H-level, the output signal of inverter 91a becomes L-level, and responsively the output signal of AND circuit 91b falls to L4evel. NOR circuit 91d generates the signal at L-level in accordance with the output signal of latch 93a.

When row active command ACT is applied, latch 92b takes in and latches the signal at L-level, and latch 93b generates the signal at L-level in synchronization with the falling of clock signal CLK. Likewise, latch 92a takes in and latches the signal at L-level received from AND circuit 91b in synchronization with the rising of clock signal CLK, and subsequently latch 93a takes in and outputs the signal received from latch 92a in response to the falling of clock signal CLK. Therefore, both the output signals of latches 93a and 93b attain L-level so that count bit ACN<0> attains H-level, and count bit ACN<2> attains L-level.

Therefore, ACT counter 90 forms a so-called ternary counter, and count bit ACN<0> attains H-level every time the row active command ACT is applied three times. Thereby, main row activating signal generating circuits GEN0-GEN2 shown in FIG. 27 can be sequentially activated.

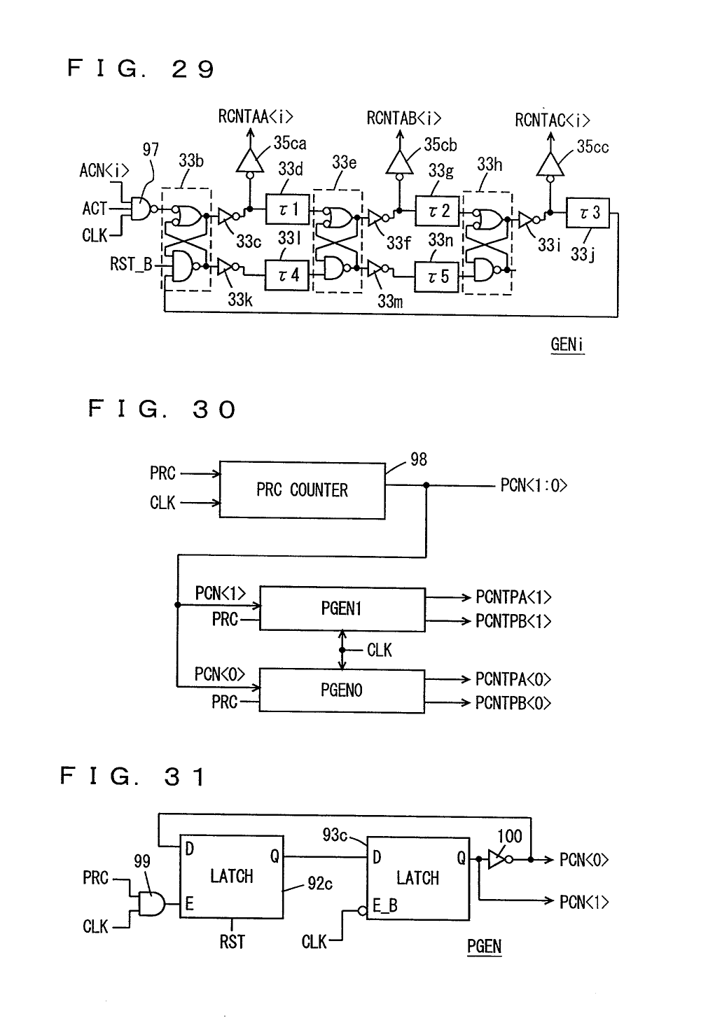

FIG. 29 shows a structure of a main row activating signal generating circuit GENi shown in FIG. 27. In FIG. 29, there is provided at an input stage of the main row activating circuit with an NAND circuit 97, which in turn receives count bit ACN<1>, row active command ACT and clock signal CLK (CLK0). Structures other than the above are the same as those of main row activation control circuit 33 shown in FIG. 10, and the corresponding portions bear the same reference numerals.

Main row activating signal generating circuit GENi generates main row control signals RCNTAA<i>-RCNTAC<i>. When count bit ACN<i> is at L-level, set/reset ffip-flop 33b at the input stage of main row activating signal generating circuit GENi is not reset, and therefore main row activating signal generating circuit GENi does not change its state. When count bit ACN<i> is at H-level, main row activating signal generating circuit GENi operates in accordance with row active command ACT, and produces main row activating signals RCNTAA<i>-RCNTAC<i> in a predetermined sequence when activated.

FIG. 30 schematically shows a structure of a main precharge control circuit in the seventh embodiment of the invention. In FIG. 30, the main precharge control circuit includes: a PRC counter 98 which counts precharge instructing command PRC in response to the rising of clock signal CLK; a main precharge activating signal generating circuit PGEN0 which is enabled when count bit PCN<0> of PRC counter 98 is at H-level, and produces main precharge activating signals RCNTPA<0> and RCNTPB<0> in accordance with clock signal CLK and precharge command PRC when enabled; and a main precharge activating signal generating circuit PGEN1 which is enabled when count bit PCN<1> of PRC counter 98 is at H-level, and produces main precharge activating signals RCNTPA<1> and RCNTPB<1> in accordance with clock signal CLK and precharge command PRC when enabled.

PRC counter 98 produces count value PCN<1:0> of 2 bits. The precharge operation period is sufficiently shorter than the row active period. Main row activating signals RCNTAA-RCNTAC control the row-related control signals that are generated for a period from start of the row selection to the sense amplifier activation. In the precharge operation, these row-related control signals are merely reset to the standby state in the precharge period, and the pulse widths of main precharge activating signals RCNTPA and RCNTPB can be shorter than the pulse widths of main row activating signals RCNTAA-RCNTAC. Therefore, the fast operation can be sufficiently achieved even with the structure, in which two main precharge activating signal generating circuits PGEN 1 and PGEN0 are employed, and are alternately enabled.

FIG. 31 schematically shows a structure of main precharge activating signal generating circuits PGEN0 and PGEN1 shown in FIG. 30. Since these main precharge activating signal generating circuits PGEN0 and PGEN 1 have the same structure, FIG. 31 shows representatively them as a main precharge activating signal generating circuit PGEN.

In FIG. 31, main precharge activating signal generating circuit PGEN includes: an AND circuit 99 which receives precharge command PRC and clock signal CLK; a latch 92c which receives on an input E thereof the output signal of AND circuit 99; a latch 93c which takes in the output signal of latch 92c in accordance with clock signal CLK applied to an input E_B thereof, and an inverter circuit 100 which inverts the output signal of latch 93c, and produces count bit PCN<1>. The output signal of inverter circuit 100 is also applied to an input D of latch 92c.

In accordance with reset signal RST, latch 92c resets an output signal thereof to L-level. These latches 92c and 93c have the same structures as latches 92 and 93 shown in FIGS. 28B and 28C, respectively. Inverter circuit 96d (see FIG. 28C) at the output stage of latch 93c has the drive capability equal to that of inverter circuit 100. This achieves equal signal transmission delays for count bits PCN<1:0> sent to the local control circuit, which will be described later.

When main precharge activating signal generating circuit PGEN shown in FIG. 31 is in the initial state, the output signal of latch 92c is at L-level, and the output signal of latch 93c is at L-level. Thus, count bit PCN<0> is at H-level, and count bit PCN<1> is at L-level. This state is kept until precharge command PRC is applied.

When precharge command PRC is applied, latch 92c takes in count bit PCN<0> in synchronization with the rising of clock signal CLK, and raises its output signal to H-level. When clock signal CLK attains L-level, latch 93c takes in the output signal of latch 92c , and raises its output signal, i.e., count bit PCN<1> to H-level, and count bit PCN<0> attains L-level.

When precharge command PRC is applied again, latch 92c takes in count bit PCN<0> at L-level, and the output signal thereof attains L-level. When clock signal CLK attains L-level, latch 93c takes in the signal at L-level of latch 92c, and sets count bit PCN<1> to L-level and count bit PCN<0> to H-level.

In main precharge activating signal generating circuit PGEN shown in FIG. 31, count bits PCN<0> and <PCN1> are alternately driven to H-level upon each application of precharge instructing command PRC, and main precharge activating signal generating circuits PGEN0 and PGEN1 shown in FIG. 30 are alternately activated.

As shown in FIGS. 27 and 30, main row activating signals RCNTPA-RCNTPB are activated in a predetermined sequence when the row active command is applied, and main precharge activating signals RCNTPA and RCNTPB are activated in a predetermined sequence when the precharge command is applied. No bank address is combined. Even when the bank structure changes, therefore, it is not necessary to change the structure of main row-related control signal generating circuit in the main control circuit, and no change in circuit structure is required even in the case of the bank change.

More specifically, by designing and optimizing one row-related main control circuit, the resultant circuit structure can be adapted to a structure of any number of the banks, and the design efficiency is significantly improved. Even if the banks increase in number, no increase in number of the control circuits and the control signals occurs in row-related main control circuit, and therefore the layout area can be significantly reduced as compared with the prior art.

The row-related main control circuit can be adapted to any bank structure and the any array structure (the numbers of banks, arrays and memory blocks). Thus, an optimum circuit structure suitable for a module generator performing automatic arrangement and interconnection can be achieved so that the arrangement and interconnection of the row-related main control circuits can be effectively performed. Thus, the design efficiency can be improved.

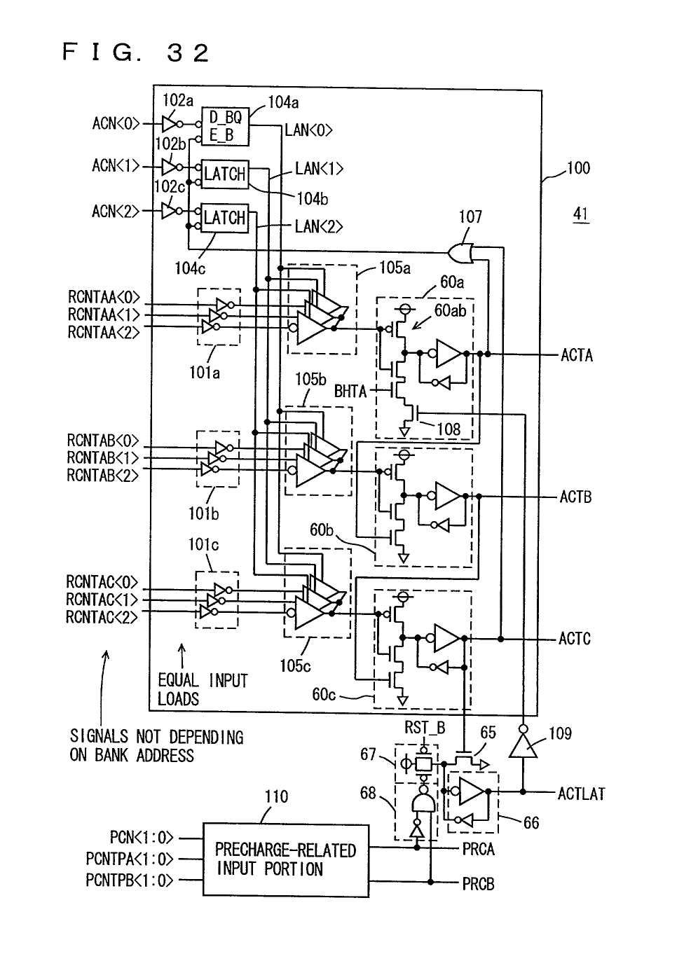

FIG. 32 shows a structure of a row-related local control circuit 41 included in the local control circuit. Row-related local control circuit 41 shown in FIG. 32 includes: an act-related input portion 100 for producing internal row control signals ACTA, ACTB and ACTC; and a prechargerelated input portion 110 for producing internal precharge control signals PRCA and PRCB in accordance with main precharge activating signals RCNTP<1:0> and RCNTPB<1:0> and precharge count bits PCN<1:0>.

Act-related input portion 100 includes: an input circuit 10 la which receives main row activating signals RCNTAA<2:0>; an input circuit 10lb which receives main row activating signals RCNTAB<2:0> in parallel; an input circuit 10lcb which receives main row activating signals RCNTAC<2:0> in parallel; input inverter buffer circuits 102a-102c which receives count bits ACT<2:0>, respectively; latches 104a-104c which latch the output signals of input inverter buffer circuits 102a-102c, and produce latch count bits LAN<2:0>, respectively; a tristate buffer 105a which includes tristate inverter buffers provided corresponding to respective latch circuits 104a-104c, and buffers the main row-related control signal RCNTAA<2:0> sent from input circuit 101a in accordance with latch count bits LAN<2:0> for application to input buffer circuit 60a; a tristate inverter buffer 105b which is selectively enabled in accordance with latch count bits LAN<2:0>, and buffers and inverts the main row-related control signals RCNTAB<2:0> sent from input circuit 101b for application to input buffer circuit 60b; a tristate inverter buffer 105c which is selectively enabled in accordance with latch count bits LAN<2:0>, and buffers the main row-related control signals RCNTAC<2:0> sent from input circuit 101c for application to input buffer circuit 60c; and an OR circuit 107 which receives internal row control signals ACTA and ACTC to apply a resultant signal the latch inputs of latches 104a-104c.

Each of input circuits 101a-101c includes inverter circuits of 3 bits, which are provided corresponding to the main row control signals of 3 bits, respectively, and inverts the corresponding main row-related control signals for application to tristate inverter buffers 105a-105c, respectively.

Tristate inverter buffers 105a-105c includes tristate inverter buffers provided corresponding to the inverters in corresponding input circuit 101a, 101b and 101c, respectively, and are enabled to invert the output signals of the inverters in corresponding input circuit 101a, 101b and 101c, respectively, when corresponding latch count bits LAN<2:0> are at H-level and active. The tristate inverter buffer circuits included in tristate inverter buffers 105a-105c attain the output high-impedance state when the corresponding count bits are at L-level and inactive.

The structures of input buffer circuits 60a-60c are the same as the structures shown in FIG. 18 except for the following points. Input buffer circuit 60a producing internal row control signal ACTA includes an N-channel MOS transistor 108, which in turn is arranged between a MOS transistor receiving a block hit signal BHTA and the ground node, and receives a latched row activating signal ACTLAT on a gate thereof via an inverter 109. When the corresponding memory block is selected and a row is in the selected state, the precharge command is to be applied, and latched row activating signal ACTLAT is at H-level, and responsively the output signal of inverter circuit 109 is at L-level. In input buffer circuit 60a, therefore, input buffer 60ab in the input stage generates the signal at H-level regardless of the output signal of the tristate inverter buffer 105a, and internal row control signal ACTA is kept at L-level. Thus, even if block hit signal BHTA is driven to the active state when the corresponding memory block is in the selected state, the memory block is not activated again. Thereby, multiple selection of the word lines in the memory block can be prevented, and circuit malfunction can be prevented.

Latches 104a-104c have the structure similar to that of latch 93 shown in FIG. 28C. When the output signal of OR circuit 107 attains H-level, these latches 104a-104c enter the latching state, and the value of internal latched count bits ACT<2:0> do not change even when the value of count bits ACT<2:0> change. In accordance with latched count bits LAN<2:0>, the corresponding tristate inverter buffer in each of tristate inverter buffers 105a-105c operates to buffer and apply the corresponding main row-related control signal to input buffer circuits 60a-60c at the next stage.

Thus, input buffer circuit 60a is enabled to enter the state of waiting for the change in main row activating signals RCNTAA<2:0>. In tristate inverter buffer 105a which is in the above state, one tristate inverter buffer circuit is made active in accordance with latch count bits LAN<2:0>. When main row activating signal RCNTAA change, corresponding input circuit 101a and tristate inverter buffer 105a apply to input buffer circuit 60a one of the main row activating signals RCNTAA<2:0>, that is, the main row activating signal corresponding to the latched count bit in the selected state among latched count bits LAN<2:0>. When input buffer circuit 60a drives internal row control signal ACTA to the active state of H-level, the output signal of OR circuit 107 attains H-level, and latches 104a-104c attain the latch state. In accordance with the activation of internal row control signal ACTA, one of main row activating signals RCNTAB<2:0> and one of main row activating signals RANTAC<2:0> are subsequently applied to tristate inverter buffers 105b and 105c via input circuits 101b and 101c, respectively. Responsively, input buffer circuits 60b and 60c sequentially activate internal row control signals ACTB and ACTC, respectively.

Accordingly, when latches 104a-104c are in the latch state, main row activating signals RCNTAB<2:0> and RCNTAC<2:0>, which are activated subsequently to activation of main row activating signals RCNTAA<2:0>, can be accurately taken into act-related input portion 100, to produce internal row control signals ACTB and ACTC even if the count value of count bits ACN<2:0> changes. Thus, the row selection can be accurately performed in the addressed memory block even if row active command ACT is successively applied at high speed as shown in FIG. 26.

When internal row control signal ACTC attains L-level, internal row control signal ACTA is already at L-level, and the output signal of OR circuit 107 attains L-level so that latches 104a-104c can take in count bits ACN<2:0>, respectively. Thereby, new count bits can be taken in after all internal row control signals ACTA-ACTC are once activated and then become inactive.

Precharge-related input portion 110 has the structure similar to that of act-related input portion 100 described above. More specifically, input inverter circuits are provided for respective main precharge activating signals RCNTPA<1:0>. In each input inverter circuit, tristate inverter buffers are selectively activated in accordance with the output signals of the latch circuits latching count bits PCN<1:0>, and internal precharge control signal PRC is activated. A similar structure is employed for precharge activating signals RCNTP<1:0> for activating internal precharge control signal PRCB.

In the structure of act-related input portion 100 shown in FIG. 32, input inverter circuits 102a-102c and the input inverter circuits of input circuits 101a-101c have the same input load (input impedance) similarly to the previous structure, and all the loads for count bits ACT<2:0> and main row activating signals RCNTAA<2:0>, RCNTAB<2:0> and RCNTAC<2:0> are equal to each other, so that the skew is prevented.

In the foregoing structure, three sets of circuits are employed for generating the main row control signals, and two sets of precharge activating signal generating circuits are employed for producing the main precharge control signals. However, these circuits may be increased in number, so that fast operations can be performed even if the frequency of clock signal further increases. The number of row activating signal generating circuits and the number of precharge activating signal generating circuits can be determined appropriately in accordance with the frequency of clock signal CLK and the pulse widths of internal row/precharge control signals. It is merely required that internal row control signals ACTA-ACTC are activated and deactivated within a period between times T4 and T1 shown in FIG. 26.

According to the seventh embodiment of the invention, as described above, a plurality of sets of main row activating signal generating circuits and a plurality of sets of main precharge activating signal generating circuits are provided, and these sets of the circuits are sequentially activated in accordance with the count value. Thus, the semiconductor memory device capable of fast operation is achieved. Further, the main row activating signals and the main precharge activating signals are control signals independent of the bank address, and the circuits for generating these signals are independent of the number of banks. Thus, it is not necessary to change the structures of these circuits even in bank expansion, and the structure can be easily adapted to the bank expansion and to the change in number of the memory blocks.

Eighth Embodiment

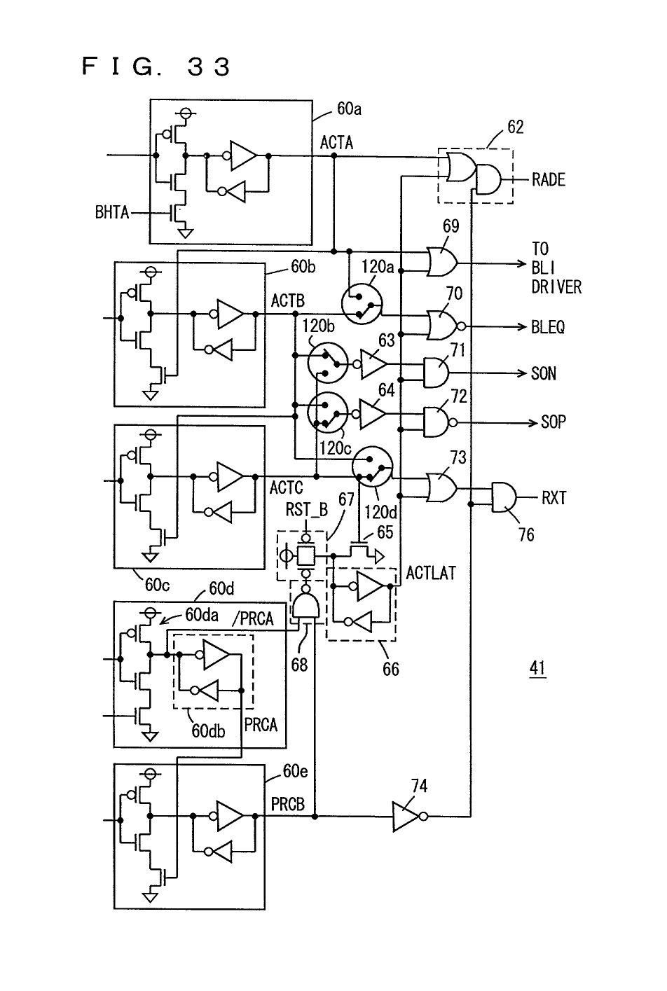

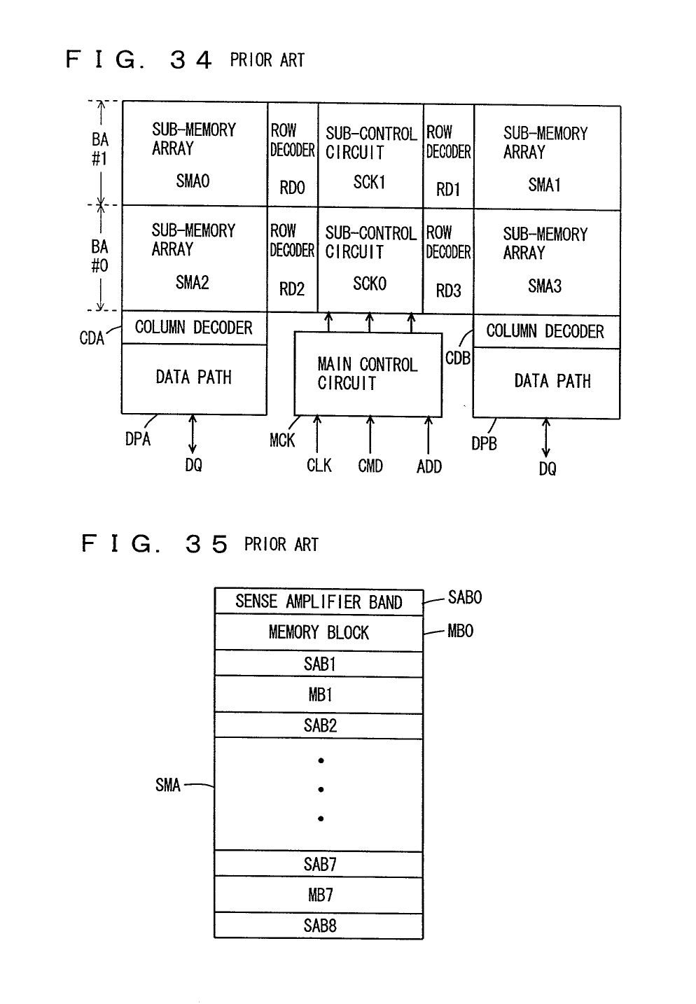

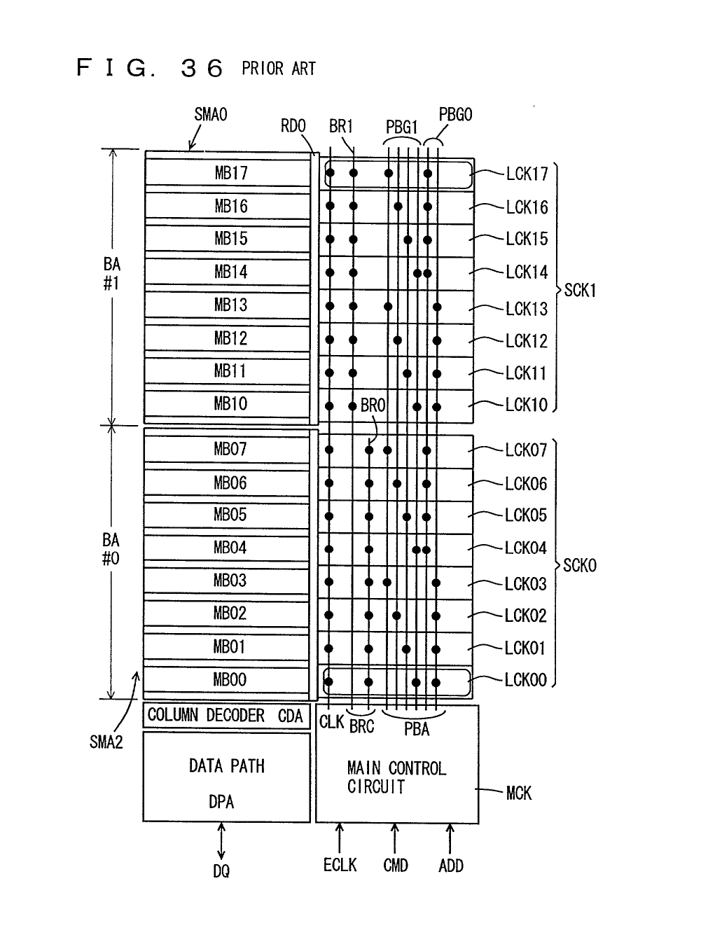

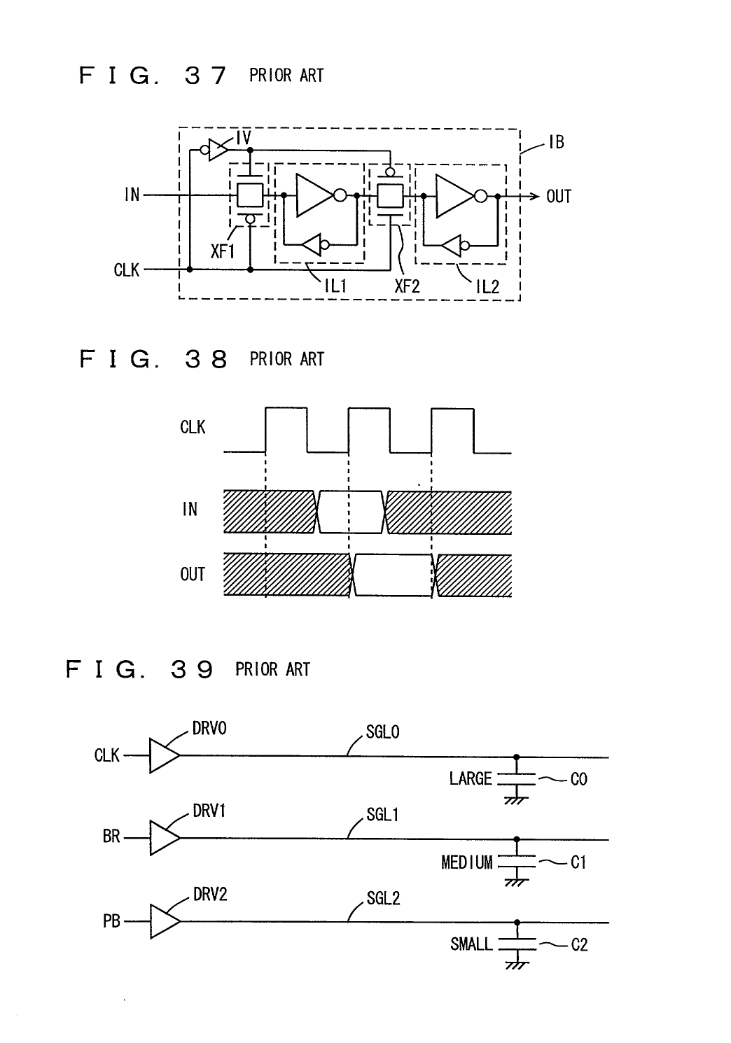

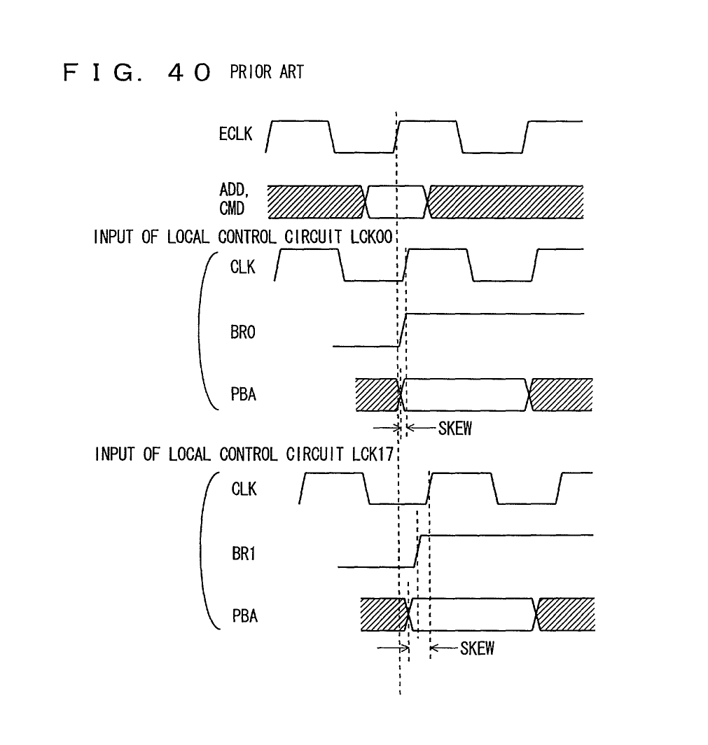

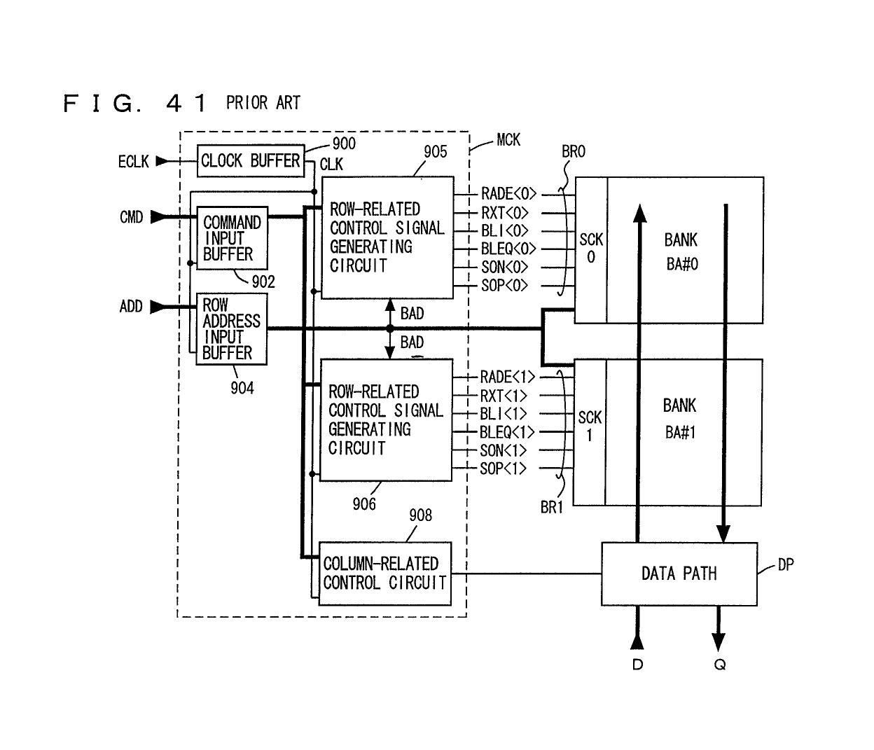

FIG. 33 shows a structure of a row-related local control circuit according to an eighth embodiment of the invention. Row-related local control circuit 41 shown in FIG. 33 differs from the row-related local control circuit shown in FIG. 18 in the following points. NOR gate 70 which produces bit line equalize instruction signal BLEQ is supplied with an output signal of a select circuit 120a selecting one of internal row control signals ACTA and ACTB and latch row activating signal ACTLAT.

A select circuit 120b for selecting one of internal row control signals ACTB and ACTC is provided for AND circuit 71 which in turn produces sense amplifier activating signal SON. The output signal of select circuit 120b is applied to AND circuit 71 via inverter 63.

A select circuit 120c for selecting one of internal row control signals ACTB and ACTC is provided for NAND circuit 72 which in turn produces sense amplifier activating signal SOP. The output signal of select circuit 120c is applied to NAND circuit 72 via inverter 64.

A select circuit 120d for selecting one of internal row control signals ACTB and ACTC is provided for AND circuit 76 producing word line drive timing signal RXT. The output signal of select circuit 120d is applied to AND circuit 76 via OR circuit 73, which in turn receives the output signal of select circuit 120d and the latched row activation signal ACTLAT.

By these select circuits 120a-120d, it is possible to change the activation timing of the respective internal row control signals.

Logic circuit 68 is supplied with a complementary output signal /PRCA of input inverter buffer 60da in precharging input buffer circuit 60d. Therefore, logic circuit 68 is formed of an NAND gate in the eighth embodiment.

Structures other than the above are the same as those shown in FIG. 18. The corresponding portions bear the same reference numerals, and description thereof is not repeated.

In the structure shown in FIG. 33, the timing of deactivation of bit line equalize instructing signal BLEQ can be determined by one of internal row control signals ACTA and ACTB. Further, the activation timing of sense amplifier activating signals SON and SOP can be determined by one of internal row control signals ACTB and ACTC.

When the sequence of edges of rising and falling of main row activating signals RCNTAA-RCNTAC is fixed, activation and deactivation of internal row control signals ACTA-ACTC are accordingly performed at fixed timings. For adjusting the timings of internal row-related control signals, the activation timings of internal row-related control signals can be adjusted in accordance with the delay times between internal row control signals ACTA-ACTC. Further, it may be required or desired to delay the internal row-related control signals by an extent equal to or larger than the phase difference between the edges of the internal row control signals. This delay can be achieved by utilizing a further later edge of internal row control signals ACTA-ACTC.

By these select circuits 120a-120d, it is possible to change the activation sequence of the row-related control signals. For example, sense amplifiers may have such transistor characteristics that the sense operation can be performed more fast and stably by simultaneously activating the N- and P-sense amplifiers (e.g., in the case where a P-sense power supply transistor has a slow response). In this case, select circuits 120b and 120c are adapted to select internal row control signal ACTB, so that sense amplifier activating signals SON and SOP can be simultaneously activated in accordance with internal row control signal ACTB. Naturally, the activation timing of sense amplifier activating signal SON may be interchanged with that of sense amplifier activating signal SOP. This is true also to word line drive timing signal RXT and bit line equalize instructing signal BLEQ. For example, if the driving speed of a selected word line is slow, word line drive timing signal RXT may be activated in accordance with internal row control signal ACTB with a faster timing.

The same is also true for the relationship between row address decode enable signal RADE and bit line equalize instructing signal BLEQ. For example, the activation of address decode enable signal RADE and the deactivation of bit line equalize instructing signal BLEQ may be performed in accordance with internal row control signal ACTA.

More specifically, the timing adjustment of the row-related control signals in row-related local control circuit is effected by select circuits 120a-120d. Select circuits 120a-120d occupy a smaller area than the delay circuits. For example, if select circuits 120a-120d have the connection paths merely formed of mask metal interconnection lines, select circuits 120a-120d occupy the area similar to that of contact holes. Therefore, it is not necessary to arrange a delay circuit for timing adjustment in row-related local control circuit 41, and an area of row-related local control circuit 41 can be reduced.

These select circuits 120a-120d may be formed of multiplexers, of which connection paths are switched in accordance with select signals (see FIG. 23).

In the structure shown in FIG. 33, input buffer circuit 60a may be configured to be disabled when latch row activating signal ACTLAT is active and at H-level (see FIG. 32).

Each of select circuits 120a-120d shown in FIG. 33 is a two-to-one select circuit. However, each of select circuits 120a-120d may be a threeto-one select circuit.

The first to eighth embodiments have been described in connection with the structure of the DRAM merged with the logic. However, the present invention can be applied to various semiconductor memory devices other than such embedded DRAM, provided that the memory devices operate in synchronization with a clock signal.

As described above, the present invention can provide the semiconductor memory device, which can achieve an excellent design efficiency, can be adapted to the bank change within a short time, and can operate fast and stably.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device comprising:
a memory array including a plurality of memory cells arranged in rows and columns;
main control circuitry for producing a plurality of main control signals having different phases in response to a row-related instructing signal instructing an operation related to row selection in said memory array; and
sub-control circuitry receiving said plurality of main control signals, for producing sub-control signals greater in number than said plurality of main control signals, said sub-control signals being signals for controlling the operation instructed by said row-related instructing signal.

2. The semiconductor memory device according to claim 1, wherein
said row-related instructing signal is either a signal instructing the row selection or a signal instructing completion of a row selecting operation.

3. The semiconductor memory device according to claim 1, further comprising a plurality of banks activated independently of each other, wherein
said plurality of main control signals are independent of a signal specifying a bank among said plurality of banks.

4. The semiconductor memory device according to claim 1, wherein
said main control circuitry includes a plurality of control signal generating circuits activated sequentially to produce said plurality of main control signals in response to said row-related instructing signal.

5. The semiconductor memory device according to claim 4, wherein
said main control circuitry further includes a count circuit for counting said row-related instructing signal, and sequentially activating said plurality of control signal generating circuits in accordance with a count value thereof.

6. The semiconductor memory device according to claim 1, wherein
said memory array is divided into a plurality of memory blocks each having a plurality of memory cells,
said sub-control circuitry includes a plurality of sub-control circuits provided corresponding to said plurality of memory blocks, respectively, and
each of said plurality of sub-control circuits includes a buffer circuit provided corresponding to each of said plurality of main control signals so that line loads of said plurality of main control signals are equal to each other.

7. The semiconductor memory device according to claim 1, wherein
said memory array is divided into a plurality of memory blocks each having a plurality of memory cells,
said sub-control circuitry includes a plurality of sub-control circuits provided corresponding to said plurality of memory blocks, and
said plurality of main control signals are transferred to said plurality of sub-control circuits with a same line load, respectively.

8. The semiconductor memory device according to claim 7, wherein said plurality of main control signals are transmitted through signal lines of a same interconnection length.

9. The semiconductor memory device according to claim 1, wherein
said main control circuitry generates the main control signals of three phases as said plurality of main control signals when said row-related instructing signal instructs the row selection, and
said sub-control circuitry produces at least four sub-control signals required for said row selection in response to said main control signals of three phases.

10. The semiconductor memory device according to claim 1, wherein said main control circuitry generates the main control signals of M phases as said plurality of main control signals when said row-related instructing signal instructs the row selection, and
said sub-control circuitry activates N sub-control signals required for said row selection at different timings in response to said main control signals of M phases, with M and N satisfying a relation of N>M, and 2M ≧N.

11. The semiconductor memory device according to claim 1, wherein
said main control circuitry includes:
a first control circuit for activating a first main control signal in response to a row selection instruction by said row-related instructing signal,
a second control circuit for activating a second main control signal in response to activation of said first main control signal, and deactivating said second main control signal in response to deactivation of said first main control signal, and
a third control circuit for activating a third main control signal in response to activation of said second main control signal, and deactivating said third main control signal in response to deactivation of said second main control signal; and
said first control circuit deactivates said first main control signal in response to activation of said third main control signal.

12. The semiconductor memory device according to claim 11, further comprising:
a first delay circuit arranged between the first and second control circuits, for delaying said first main control signal for application to said second control circuit;
a second delay circuit arranged between the second and third control circuits for delaying said second main control signal for application to said third control circuit; and
a third delay circuit arranged between the third and first control circuits for delaying activation of said third main control signal for application to said first control circuit.

13. The semiconductor memory device according to claim 12, wherein the first, second and third delay circuits have delay times set individually and independently.

14. The semiconductor memory device according to claim 12, wherein
each of the first, second and third control circuits includes a flip-flop of a set and reset type,
the first and second delay circuits delay set and reset of the flip-flops of said second and third control circuits, respectively, and
said third delay circuit delays reset of the flip-flop of said first control circuit, and the flip-flops provided in said first, second and third control circuits activate the corresponding main control signals when set.

15. The semiconductor memory device according to claim 9, wherein
said main control signals of the three phases are sequentially activated in a fixed sequence.

16. The semiconductor memory device according to claim 1, wherein
said main control circuitry generates the main control signals of at least two phases as said plurality of main control signals when said row-related instructing signal instructs completion of the row selecting operation.

17. The semiconductor memory device according to claim 16, wherein
said main control circuitry includes:
a first control circuit for activating a first main control signal in response to said row-related instructing signal; and
a second control circuit for activating a second main control signal in response to activation of said first main control signal, and deactivating said second main control signal in response to deactivation of said first main control signal, and
said first control circuit deactivates said first main control signal in response to activation of said second main control signal.

18. The semiconductor memory device according to claim 17, wherein
said main control circuitry further includes:
a first delay circuit arranged between the first and second control circuits for delaying said first main control signal for transmission to said second control circuit; and
a second delay circuit arranged between the second and first control circuits for delaying said second main control signal for application to said first delay circuit.

19. The semiconductor memory device according to claim 18, wherein the first and second delay circuits have delay times set individually and independently.

20. The semiconductor memory device according to claim 1, wherein
said main control circuitry includes a delay circuit for sequentially activating said plurality of main control signals, and
said delay circuit includes:
a plurality of delay stages each for delaying a received signal;
a plurality of select circuits, provided corresponding to said plurality of delay stages, respectively, each for selecting one of an output signal of a corresponding delay stage and an input signal to be delayed to apply a selected one to a delay stage in a next stage in the delay stages, and
a plurality of metal interconnection switches provided corresponding to said plurality of select circuits for producing signals determining selecting paths of corresponding select circuits, respectively, the metal interconnection switches each having a voltage level of the signal to be generated determined by a metal interconnection line.

21. The semiconductor memory device according to claim 1, wherein
said main control circuitry includes a delay circuit for sequentially activating said plurality of main control signals,
said delay circuit includes:
a plurality of cascaded delay stages each for delaying a received signal,
a plurality of select circuits, provided corresponding to said plurality of delay stages, respectively, each for selecting one of an output signal of a corresponding delay stage and an input signal to be delayed for application to a delay stage in a next stage in the delay stages, and
a plurality of select signal generating circuits, provided corresponding to said plurality of select circuits, each for producing a signal determining a selection path of a corresponding select circuit, each of the select signal generating circuits having a voltage level of the signal to be generated set through programming of a fuse element.

22. The semiconductor memory device according to claim 1, wherein
said main control circuitry includes a delay circuit for sequentially activating said plurality of main control signals, and
said delay circuit includes:
a plurality of delay stages each for delaying a received signal;
a plurality of select circuits, provided corresponding to the respective delay stages, each for selecting and apply one of an output signal of a corresponding delay stage and an input signal to be delayed to a delay stage at a next stage in the delay stages; and
a select signal generating circuit for generating a select signal setting one of said plurality of select circuits to a state for selecting said input signal, said select signal generating circuit including a decode circuit for decoding an output signal of a fuse program circuit to generate said select signal.

23. The semiconductor memory device according to claim 22, wherein
said fuse program circuit includes:
a circuit for producing a default indicating an initial delay value,
a circuit for generating a delay value to be set through a programming of a fuse element; and
a logic circuit for performing a logical operation on said default and the delay value programmed by the fuse element.

24. The semiconductor memory device according to claim 1, further comprising:
an address input circuit for taking in and buffering an externally applied address signal to produce an internal address for application to said sub-control circuitry.

25. The semiconductor memory device according to claim 24, wherein
said memory array is divided into a plurality of memory blocks each having a plurality of memory cells,
said sub-control circuitry includes a plurality of sub-control circuits provided corresponding to said plurality of memory blocks, respectively,
the internal address generated from said address input circuit is applied to each of said sub-control circuits, and
an input load of a circuit supplied with the internal address of each of said sub-control circuits is equal to an input load of a circuit supplied with said plurality of main control signals in the sub-control circuits.

26. The semiconductor memory device according to claim 24, wherein
each of the sub-control circuits includes an address buffer receiving said internal address, and a control buffer receiving the main control signals, and
said address buffer and said control buffer include input buffers of a same structure.

27. The semiconductor memory device according to claim 24, wherein
said memory array is divided into a plurality of memory blocks each having a plurality of memory cells,
said sub-control circuitry includes a plurality of sub-control circuits provided corresponding to said plurality of memory blocks, respectively,
each of said plurality of sub-control circuits includes a block decode circuit for receiving and decoding a plurality of block address bits included in said internal address, and
said block decode circuit includes;
an input circuit for producing complementary address bits from each of said block address bits,
a switch circuit for selecting one of said complementary address bits for each block address bit, and
a decode circuit for decoding address bits received from the switch circuit to produce a block select signal for selecting a corresponding memory block.

28. The semiconductor memory device according to claim 27, wherein
said switch circuit has a connection path set through a mask metal interconnection.

29. The semiconductor memory device according to claim 24, wherein
said memory array is divided into a plurality of memory blocks each having a plurality of memory cells,
said sub-control circuitry includes a plurality of sub-control circuits provided corresponding to said plurality of memory blocks, respectively,
each of said plurality of sub-control circuits includes;
a block decode circuit for receiving and decoding a plurality of block address bits included in said internal address, and
said block decode circuit includes:
an input circuit for producing complementary address bits for each of the block address bits;
a select circuit for selecting one of said complementary address bits for each block address bit; and
a decode circuit for decoding address bits selected by said select circuit to produce a block select signal specifying a corresponding memory block.

30. The semiconductor memory device according to claim 1, wherein
said memory array is divided into a plurality of memory blocks each having a plurality of memory cells,
said sub-control circuitry includes a plurality of sub-circuits provided corresponding to said plurality of memory blocks, respectively, and
each of said plurality of sub-control circuits includes;
a block decode circuit for decoding a block address included in said internal address to produce a block select signal specifying a corresponding memory block, and
a local control signal generating circuit for taking in the plurality of main control signals sent from said main control circuitry, and producing said plurality of sub-control signals when the block select signal generated from said block decode circuit is active.

31. The semiconductor memory device according to claim 30, wherein
each said sub-control circuit includes;
a first buffer circuit for taking in a first main control signal among said plurality of main control signals and producing a first internal main control signal in response to activation of said block select signal,
a second buffer circuit for taking in a second main control signal among said plurality of main control signals and producing a second internal main control signal in response to activation of said first internal main control signal received from said first buffer circuit, and
at least one buffer circuit provided corresponding to a remaining main control signal(s) among said plurality of main control signals for taking in a corresponding main control signal(s), and producing an internal main control signal(s) in response to activation of an internal main control signal on a preceding stage.

32. The semiconductor memory device according to claim 1, wherein
said sub-control circuitry includes a plurality of buffer circuits, provided corresponding to said plurality of main control signals, each producing an internal main control signal from a corresponding main control signal when made active, and
said plurality of buffer circuits are coupled in a chain to receive internal main control signals at preceding stages, and are each activated in response to activation of the internal main control signal on the preceding stage.

33. The semiconductor memory device according to claim 1, wherein
said main control circuitry includes a delay adjustment circuit for adjusting a delay between said plurality of main control signals, and
said sub-control circuitry produces said plurality of sub-control signals in accordance with the main control signals sent from said main control circuit and subjected to delay adjustment through the delay adjustment circuit.

34. The semiconductor memory device according to claim 1, wherein
said sub-control circuitry includes a switch circuit for changing a relationship between said plurality of main control signals and said plurality of sub-control signals.

35. The semiconductor memory device according to claim 4, wherein
said semiconductor memory device operates in synchronization with a clock signal, and said plurality of main control signals are generated in a one-shot pulse form; and
said plurality of control signal generating circuits are determined in number based on a frequency of said clock signal and a pulse width of said main control signal.

36. The semiconductor memory device according to claim 4, wherein
said semiconductor memory device includes a plurality of banks each driven to an active state independently of others, and the number of said plurality of control signal generating circuits is constant independently of the number of the banks.

37. The semiconductor memory device according to claim 1, wherein said main control circuitry generates the main control signals of at least two phases as said plurality of main control signals when said row-related instructing signal instructs the row selection.
